(19) United States
(12) Patent Application Publication
(10) Pub. No.: US 2009/0072334 A1
(43) Pub. Date: Mar. 19, 2009

(54) Semiconductor device, pre-mold package, and manufacturing method therefor

(75) Inventor: Hiroshi Saitoh, Iwata-shi (JP)

Correspondence Address: PILLSBURY WINTHROP SHAW PITTMAN LLP, P.O BOX 10500, McLean, VA, 22102, US

(73) Assignee: Yamaha Corporation, Hamamatsu-shi (JP)

(21) Appl. No.: 12/220,867

(22) Filed: Jul. 29, 2008

(30) Foreign Application Priority Data
Jul. 31, 2007 (JP) P2007-198674
Sep. 3, 2007 (JP) P2007-228361

(51) Int. Cl. H01L 23/495; H01L 21/50; B29B 11/14

(52) U.S. Cl. 257/415; 257/666; 438/123; 428/542.8; 257/E23.031; 257/E21.499

(57) ABSTRACT

A pre-mold package of a semiconductor device is constituted of a lead frame, a mold resin having a box-like shape constituted of a side wall and a bottom for mounting at least one semiconductor chip, and a cover composed of a conductive material. The lead frame includes a shield plate embedded in the bottom of the mold resin, a plurality of arms, and a plurality of external terminals that are exposed on the backside of the bottom of the mold resin. The arms are embedded in the side wall so that the distal ends thereof are exposed on the upper end of the side wall and are electrically connected to the cover. Instead of the arms, a plurality of internal terminals is included in the lead frame so that the distal ends thereof are exposed on the upper surfaces of racks formed inside of the mold resin.

### BACKGROUND OF THE INVENTION

1. Field of the Invention

The present invention relates to semiconductor devices encapsulated in pre-mold packages. The present invention also relates to manufacturing methods of semiconductor devices encapsulated in pre-mold packages.

The present application claims priority on Japanese Patent Application No. 2007-198674 and Japanese Patent Application No. 2007-228361, the contents of which are incorporated herein by reference.

2. Description of the Related Art

Conventionally, pre-mold packages have been used for encapsulating semiconductor devices incorporating semiconductor chips, wherein lead frames are integrally embedded in the bottoms of mold resins having plate-like shapes or box-like shapes and in which semiconductor chips are mounted on mold resins and are sealed with covers.

Conventionally-known semiconductor devices encapsulated in pre-mold packages have been disclosed in various documents such as Patent Document 1. In addition, various types of semiconductor devices serving as silicon condenser microphones, pressure sensors, transducers, and the like have been developed and disclosed in various documents such as Patent Document 2 and Patent Document 3.
Patent Document 1: Japanese Unexamined Patent Application Publication No. 2007-66967
Patent Document 2: Japanese Patent Application Publication No. 2004-537182
Patent Document 3: Japanese Unexamined Patent Application Publication No.

Patent Document 1 teaches a conventionally-known semiconductor device encapsulated in a pre-mold package, which serves as a pressure sensor or a microphone. Herein, a semiconductor chip is mounted on a stage that is formed in approximately the center portion of a lead frame, wherein a mold resin (which is larger than the stage) is integrally formed with the backside of the stage, and wherein the intermediate portions of interconnection leads (which are extended from the stage) are exposed on the surface of the peripheral portion of the mold resin (that are positioned externally of the stage). A metal cover (or a metal cup) is attached onto the mold resin in such a way that the peripheral portion thereof joins the peripheral portion of the mold resin so as to form a space surrounding the semiconductor chip, wherein the cover is electrically connected to the exposed portions of the interconnection leads.

The external portion of the metal cover is sealed with a resin and is integrally connected with the mold resin. The distal ends of interconnection leads and the distal ends of leads (that are arranged externally of the stage) are exposed on the backside of the mold resin; hence, they are connected to the circuitry of a substrate (or a circuit board) on which the semiconductor device is mounted.

The aforementioned semiconductor device encapsulated in a pre-mold package is characterized in that the stage of the lead frame is connected to the metal cover via the exposed portions of the interconnection leads, thus encompassing the semiconductor chip with metals. This improves the shield effect of the semiconductor device. This semiconductor device can be simply manufactured with low cost by simply molding the lead frame with a resin. In manufacturing, interconnection leads are bent upwardly; the intermediate portions thereof are exposed on the surface of the peripheral portion of the mold resin; then, the distal ends thereof are bent downwardly and are exposed on the backside of the mold resin. This increases the lengths of interconnection leads; and this increases the thickness of the peripheral portion of the mold resin because interconnection leads are bent and embedded in the mold resin.

Patent Document 2 teaches a miniature silicon condenser microphone encapsulated in a hollow housing constituted of a substrate and a cover, wherein multiple semiconductor chips are mounted on the substrate and are connected to internal terminals via wire bonding while external terminals connected to internal terminals are exposed on the backside of the housing. This type of the semiconductor device may be installed in a portable electronic device such as a cellular phone and is thus reduced in size. Patent Document 3 teaches an optical divider having a light-reception array encapsulated in a rectangular housing, wherein internal terminals are arranged along only the long side of the housing and are electrically connected to a semiconductor chip.

Specifically, the aforementioned silicon condenser microphone includes two semiconductor chips, i.e. a microphone chip and a control chip arranged inside of the housing. When internal terminals are arranged along the long side of the housing of the silicon condenser microphone (similarly to Patent Document 2), they should be concentrated at one side of the housing; this brings a limitation in reducing the size of the semiconductor device because adequate distances should be secured between internal terminals adjoining together.

The semiconductor device may be stabilized in operation and structure by uniformly arranging external terminals in the periphery of the housing. When internal terminals are collectively arranged along one side of the housing, it may be necessary to employ a complex wire drawing structure in which a lead frame may be split in order to secure interconnection between internal terminals and external terminals.

### SUMMARY OF THE INVENTION

It is an object of the present invention to provide a semiconductor device encapsulated in a pre-mold package having a simple structure, which can be thus manufactured at a low cost.

It is another object of the present invention to provide a manufacturing method of the semiconductor device encapsulated in the pre-mold package.

It is a further object of the present invention to provide a small-sized semiconductor device having a simple structure incorporating multiple semiconductor chips.

In a first aspect of the present invention, a semiconductor device encapsulated in a pre-mold package includes a lead frame, a mold resin having a box-like shape constituted of a side wall and a bottom for embedding the lead frame therein, at least one semiconductor chip mounted on the bottom of the mold resin, and a cover attached to the upper end of the side wall of the mold resin. The lead frame includes a shield plate embedded in the bottom of the mold resin, a plurality of arms extended from the shield plate, and a plurality of external terminals which are connected to either the shield plate or the semiconductor chip and are partially exposed on the backside of the bottom of the mold resin. The cover is composed of a conductive material and is electrically connected to the distal ends of the arms, which are exposed on the upper end of the side wall of the mold resin.

Since the distal ends of the arms are exposed on the upper end of the side wall of the mold resin, the lengths of the arms can be determined based on the distance between the shield plate and the upper end of the side wall, while the height of the side wall can be determined in response to the height of the arms bent upward from the shield plate; hence, it is possible to reduce the thickness of the side wall of the mold resin. Herein, the arms are embedded in the side wall of the mold resin, thus preventing bonding wires from being short-circuited with internal wirings. The lead frame has multiple arms whose distal ends are exposed on the upper end of the side wall of the mold resin and which are thus reliably and electrically connected to the cover. This improves the shield effect of the pre-mold package. In this connection, multiple arms are extended opposite the shield plate.

In a manufacturing method of the semiconductor device encapsulated in a pre-mold package, the lead frame is arranged in a cavity of an injection metal mold; the lead frame is clamped in such a way that the distal ends of the arms are depressed and elastically deformed; and then, a melted resin is injected into the cavity so as to form the mold resin. Specifically, the injection metal mold is clamped such that the shield plate is placed in contact with the lower metal mold while the distal ends of the arms are brought into contact with the upper metal mold, whereby the arms are elastically deformed so that the distal ends are pressed towards the interior surface of the upper metal mold. In this state, a melted resin is injected into the cavity of the injection metal mold, wherein it may be rarely introduced into gaps between the distal ends of the arms and the interior surface of the upper metal mold; thus, it is possible to reliably expose the distal ends of the arms from the mold resin without forming burrs.

Since the arms are extended oppositely from the shield plate, they are elastically deformed such that the lengths thereof are broadened; hence, it is possible to reliably press the distal ends of the arms in contact with the interior surface of the upper metal mold. Since the mold resin is formed while the shield plate is partially brought into contact with the lower metal mold, it is possible to prevent the shield plate from unexpectedly coming into contact with solder when the semiconductor device is mounted on a substrate (or a circuit board).

The mold resin includes the bottom for embedding the lead frame and for mounting the semiconductor chip thereon, and the side wall vertically disposed in the periphery of the bottom. The lead frame includes a shield plate embedded in the bottom, a ground terminal that is connected to the shield plate and is exposed on the backside of the bottom, a plurality of external terminals that are electrically connected to the semiconductor chip mounted on the bottom and are partially exposed on the backside of the bottom, and a plurality of arms which are bend upwardly from the shield plate and whose distal ends are exposed on an upper end of the side wall.

The pre-mold package includes the aforementioned mold resin and the cover composed of a conductive material, which is fixed to the upper end of the side wall above the semiconductor chip.

The pre-mold package further includes a sound hole establishing communication between the internal space and the external space, wherein the semiconductor chip serves as a microphone chip. The sound hole is formed in the mold resin, for example. In this case, it is possible to reduce the overall height of the pre-mold package mounted on the substrate (or the circuit board).

As described above, since the arms have reduced lengths and the side wall of the mold resin has a small thickness, it is possible to reduce the overall size of the semiconductor device, which is manufactured at a low cost. Since the lead frame is clamped by the injection metal mold while the arms are elastically deformed so that the mold resin is formed while the distal ends of the arms are pressed towards the interior surface of the upper metal mold, it is possible to reliably expose the distal ends of the arms on the upper end of the side wall of the mold resin.

In a second aspect of the present invention, a semiconductor device includes a plurality of semiconductor chips electrically connected together, a mold resin having a box-like shape constituted of a bottom having a rectangular shape and a side wall vertically disposed on the periphery of the bottom, in which the plurality of semiconductor chips is mounted on the bottom and is surrounded by the side wall, a lead frame constituted of a shield plate embedded in the bottom and positioned below the plurality of semiconductor chips, a plurality of internal terminals electrically connected to at least one of the plurality of semiconductor chips, and a plurality of external terminals electrically connected to the plurality of internal terminals and exposed from the mold resin, a plurality of racks, which are formed along the interior surface of the side wall so as to project above the bottom at respective positions that are shifted alternately in a longitudinal direction and are adjacent to the plurality of semiconductor chips and in which the plurality of internal terminals vertically runs through the plurality of racks so that the distal ends of the internal terminals are exposed on the upper surfaces of the racks, and a cover for covering the mold resin so as to form an internal space therebetween, wherein the cover is composed of a conductive material and is electrically connected to the shield plate.

In the above, the semiconductor chips are positioned to adjoin the racks that are oppositely arranged along the interior surface of the side wall of the mold resin. Compared with another structure in which internal terminals are collectively arranged in one side of the mold resin, it is possible to reduce the overall size of the semiconductor device without problem. That is, the internal terminals (whose distal ends are exposed on the upper surfaces of the racks) are distributed to the racks; hence, compared with another structure, it is possible to prevent the internal terminals from being concentrated at a prescribed region in the mold resin. The semiconductor chips are arranged in the space formed between the side wall and the racks inside of the mold resin; hence, it is possible to efficiently use the limited internal space of the mold resin.

Since the internal terminals are interconnected to the external terminals through the racks, it is possible to simplify the structure for drawing wirings in the lead frame. Since the internal terminals are upset (or overturned), it is possible to reduce the distance between the shield plate and the internal terminals, by which it is possible to increase the overall area of the shield plate.

Since the internal terminals are distributed to the racks integrally formed along the opposite side portions of the side wall of the mold resin, it is possible to simplify the structure for drawing the internal terminals and external terminals; hence, it is possible to easily distribute the external terminals (interconnected to the internal terminals) to the opposite side portions of the side wall of the mold resin.

Since the distal ends of the internal terminals are upset (or overturned), it is possible to reduce the distance between the external terminals that are distributed to the opposite side portions of the side wall of the mold resin. As a result, it is possible to remarkably reduce the overall size of the semiconductor device.

In the above, it is preferable that the shield plate be elongated in an alignment direction of the semiconductor chips inside of the bottom of the mold resin. Since the internal terminals are interconnected to the external terminals via the racks, it is possible to improve the shield effect because the shield plate is not necessarily split into parts.

Specifically, the plurality of semiconductor chips includes a microphone chip having a diaphragm and a control chip; a sound hole establishing communication between the external space and the internal space defined between the mold resin and the cover is formed to run through the cover or the mold resin; and the side wall of the mold resin has a pair of side portions, which are opposite to each other and along which the plurality of racks is integrally formed.

The aforementioned semiconductor device may serve as a silicon microphone preferably adapted to an electronic device such as a cellular phone. Because, the semiconductor device can be reduced in size; the lead frame can be simplified; and the shield effect can be improved.

In the manufacturing method of the semiconductor device, the lead frame is arranged inside of a cavity of an injection metal mold constituted of a lower metal mold and an upper metal mold; the injection metal mold is clamped so as to tightly hold the lead frame between the lower metal mold and the upper metal mold, wherein the distal ends of the internal terminals are pressed by the interior surface of the upper metal mold while the external terminals are placed in contact with the interior surface of the lower metal mold so that the internal terminals are elastically deformed; then, a melted resin is injected into the cavity so as to form the mold resin. In the clamped state, the injected resin does not enter into the gap between the distal ends of the internal terminals and the interior surface of the upper metal mold, which are fixedly positioned under pressure. That is, it is possible to reliably expose the distal ends of the internal terminals from the mold resin without forming burrs.

In this connection, a mold resin includes a bottom having a rectangular shape for substantially embedding a lead frame therein and used for mounting a plurality of semiconductor chips thereon, and a side wall vertically disposed on the periphery of the bottom. The lead frame is constituted of a shield plate embedded in the bottom, a plurality of internal terminals electrically connected to at least one of the plurality of semiconductor chips, and a plurality of external terminals that are electrically connected to the shield plate or the internal terminals and that are exposed on the backside of the bottom. A plurality of racks is formed along the interior surface of the side wall so as to project above the bottom at respective positions that are shifted alternately in the longitudinal direction and are adjacent to the plurality of semiconductor chips. The internal terminals vertically run through the racks so that the distal ends of the internal terminals are exposed on the upper surfaces of the racks.

A pre-mold package includes the aforementioned mold resin and a cover that is fixed onto the upper end of the side wall so as to cover the mold resin, wherein the cover is composed of a conductive material and is electrically connected to the shield plate.

A microphone package using the aforementioned pre-mold package is designed such that a sound hole establishing communication between the external space and the internal space surrounded by the mold resin and the cover is formed to run through the mold resin or the cover, and a microphone chip (serving as one of the semiconductor chips) is arranged inside of the internal space. When the sound hole is formed in the mold resin, it is possible to reduce the overall height of the microphone package mounted on the substrate of an electronic device, for example.

### BRIEF DESCRIPTION OF THE DRAWINGS

These and other objects, aspects, and embodiments of the present invention will be described in more detail with reference to the following drawings.

FIG. 1 is a perspective view showing a lead frame embedded in a mold resin of a semiconductor device encapsulated in a pre-mold package in accordance with a first embodiment of the present invention.

FIG. 2 is a plan view of the mold resin integrally formed together with the lead frame.

FIG. 3 is a plan view of the mold resin in which a microphone chip and a control chip are mounted on the lead frame.

FIG. 4 is a longitudinal sectional view taken along line A-A in FIG. 3 with respect to the semiconductor device attached with a cover.

FIG. 5 is a lateral sectional view taken along line B-B in FIG. 3 with respect to the semiconductor device attached with the cover.

FIG. 6 is a bottom view showing the backside of the pre-mold package.

FIG. 7 is a plan view of the lead frame.

FIG. 8 is a back view showing the backside of the lead frame shown in FIG. 7.

FIG. 9 is a cross-sectional view showing that the lead frame is mounted on a lower metal mold of an injection metal mold.

FIG. 10 is a cross-sectional view showing a clamped state in which the lead frame is clamped by the injection metal mold.

FIG. 11 is a cross-sectional view showing that a modified example of the lead frame is clamped in the injection metal mold whose lower metal mold has projections.

FIG. 12 is a cross-sectional view showing the structure of the mold resin embedding the lead frame shown in FIG. 11, which has recesses positioned to substantially match the projections of the lower metal mold.

FIG. 13 is a perspective view showing a lead frame embedded in a mold resin of a semiconductor device encapsulated in a pre-mold package in accordance with a modified example of the first embodiment.

FIG. 14 is a plan view of the lead frame shown in FIG. 13.

FIG. 15 is a back view showing the backside of the lead frame shown in FIG. 13.

FIG. 16 is a plan view showing that a microphone chip and a control chip are mounted on a mold resin integrally formed with the lead frame in the semiconductor device shown in FIG. 13.

FIG. 17 is a back view showing the backside of the pre-mold package shown in FIG. 13.

FIG. 18 is a longitudinal sectional view taken along line C-C in FIG. 17, which shows the pre-mold package having a cover.

FIG. 19 is an enlarged sectional view showing that the lead frame is introduced into an injection metal mold.

FIG. 20 is an enlarged sectional view showing that the lead frame is clamped by the injection metal mold.

FIG. 21 is a perspective view showing a lead frame embedded in a mold resin of a semiconductor device encapsulated in a pre-mold package in accordance with a second embodiment of the present invention.

FIG. 22 is a plan view of the mold resin integrally formed together with the lead frame.

FIG. 23 is a plan view of the mold resin in which a microphone chip and a control chip are mounted on the lead frame.

FIG. 24 is a longitudinal sectional view taken along line A-A in FIG. 23 with respect to the semiconductor device attached with a cover.

FIG. 25 is a lateral sectional view taken along line B-B in FIG. 23 with respect to the semiconductor device attached with the cover.

FIG. 26 is a bottom view showing the backside of the pre-mold package.

FIG. 27 is a plan view of the lead frame.

FIG. 28 is a back view showing the backside of the lead frame shown in FIG. 27.

FIG. 29 is a perspective view showing the exterior appearance of the semiconductor device.

FIG. 30 is a cross-sectional view showing that the lead frame is mounted on a lower metal mold of an injection metal mold.

FIG. 31 is a cross-sectional view showing a clamped state in which the lead frame is clamped by the injection metal mold.

FIG. 32 is a perspective view showing a lead frame embedded in a mold resin of a semiconductor device encapsulated in a pre-mold package in accordance with a modified example of the second embodiment.

FIG. 33 is a plan view of the lead frame shown in FIG. 32.

FIG. 34 is a back view of the lead frame shown in FIG. 33.

FIG. 35 is a plan view of the mold resin in which a microphone chip and a control chip are mounted on the lead frame.

FIG. 36 is a back view of the mold resin shown in FIG. 35.

FIG. 37 is a longitudinal sectional view taken along line C-C in FIG. 36 with respect to the semiconductor device attached to a cover.

FIG. 38 is a cross-sectional view showing that the lead frame is mounted on a lower metal mold of an injection metal mold.

FIG. 39 is a cross-sectional view showing a clamped state in which the lead frame is clamped by the injection metal mold.

### DESCRIPTION OF THE PREFERRED EMBODIMENTS

The present invention will be described in further detail by way of examples with reference to the accompanying drawings.

### 1. First Embodiment

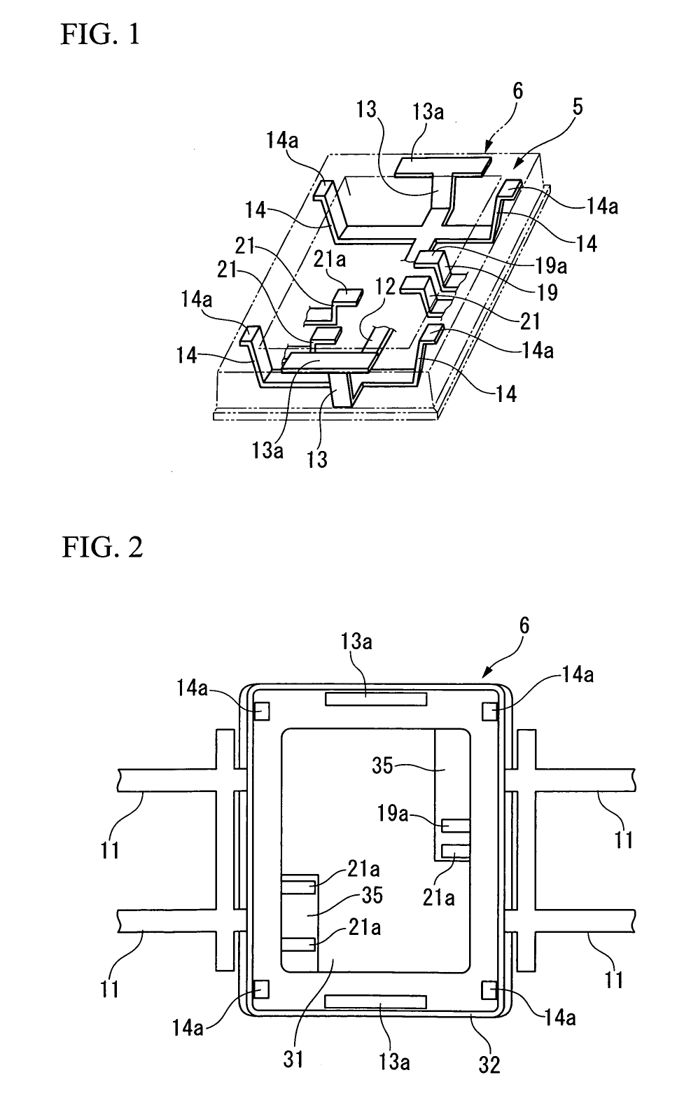

A semiconductor device 1 encapsulated in a pre-mold package 4 will be described with reference to FIGS. 1 to 10 in accordance with a first embodiment of the present invention. The semiconductor device 1 serving as a microphone incorporates two semiconductor chips, i.e. a microphone chip 2 and a control chip 3.

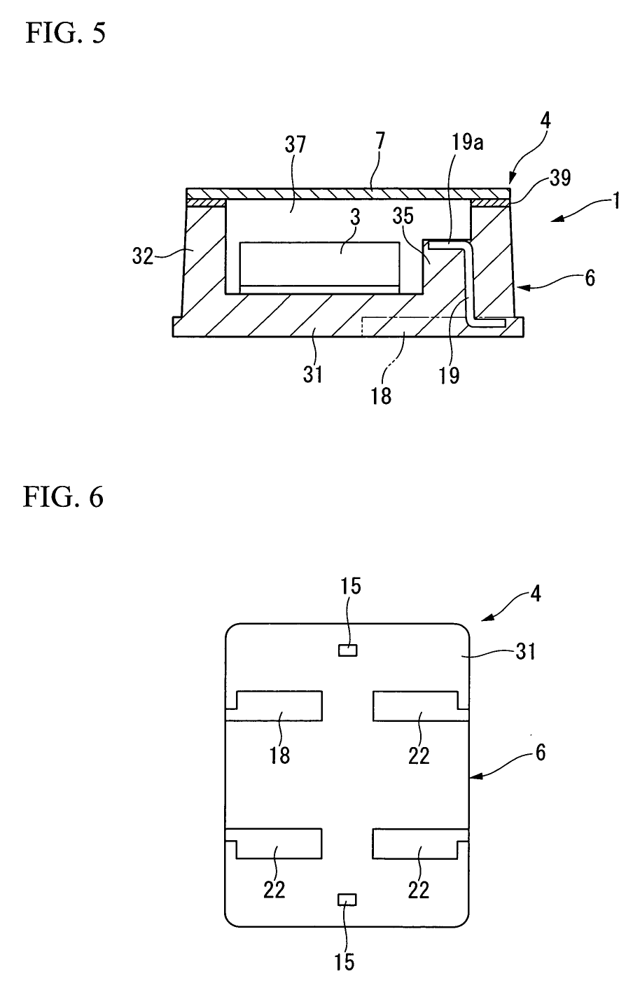

As shown in FIGS. 4 and 5, the pre-mold package 4 is constituted of a lead frame 5, a mold resin 6 having a box-like shape, which is integrally formed with the lead frame 5, and a cover 7 for covering the upper portion of the mold resin 6.

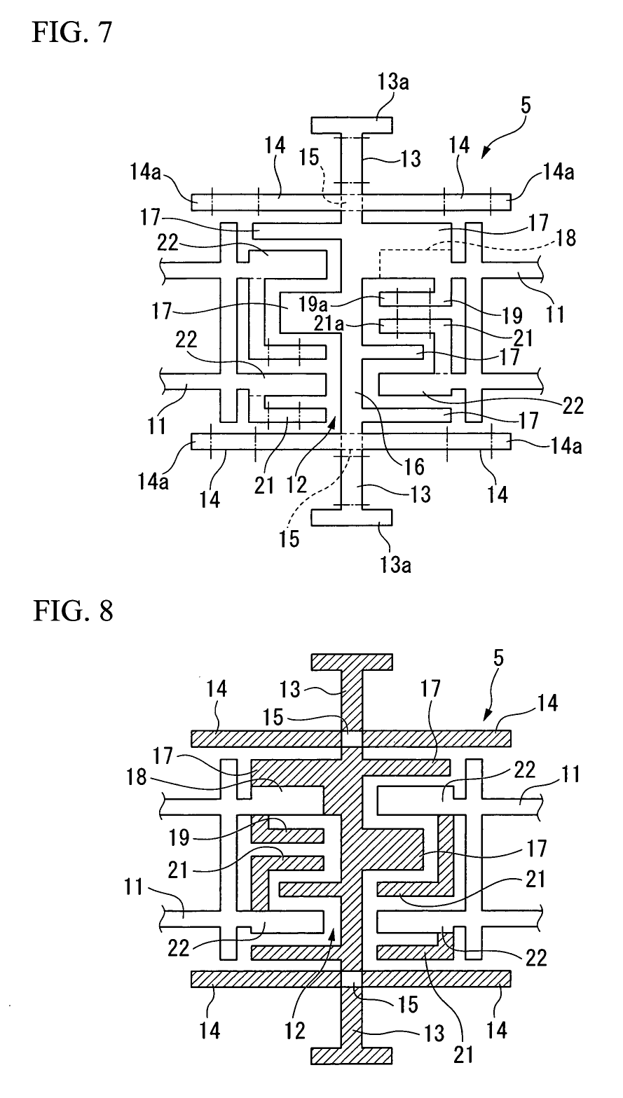

A metal plate (not shown) is subjected to press working so as to form a plurality of lead frames (each corresponding to the lead frame 5 shown in FIG. 7) which are linearly arranged. In FIG. 7, a vertical direction is referred to as a longitudinal direction, and a horizontal direction is referred to as a lateral direction. Two internal frames 11 are formed in the intermediate portion of the lead frame 5 in its longitudinal direction. The lead frame 5 is connected with another lead frame (not shown) adjoining together via the internal frames 11.

A shield plate 12, which is elongated in the longitudinal direction, is formed in the center portion of the lead frame 5 in the lateral direction. Three arms are formed at each of the opposite ends of the shield plate 12 in the longitudinal direction; that is, a main arm 13 is elongated in the longitudinal direction, and a pair of sub-arms 14 is elongated oppositely in the lateral direction perpendicularly to the main arm 13. Each of the sub-arms 14 has the same width along the overall length thereof; hence, all of distal ends 14a of the sub-arms 14 have the same width. A distal end 13a of the main arm 13 is elongated in the lateral direction; hence, the main arm 13 has a T-shape in the overall view. The arms 13 and 14 branch away from the base ends of the arms 13 and 14, the backsides of which are increased in thickness in comparison with other portions of the arms 13 and 14 so as to form projections 15, which project downwardly in the thickness direction. That is, a pair of the sub-arms 14 is oppositely stretched from each of the two projections 15 that are formed at opposite ends of the shield plate 12. In other words, the two projections 15 are disposed in the longitudinal direction between the two main arms 13.

A linear portion 16 extended in the longitudinal direction is formed in the intermediate position of the shield plate 12 between the arms 13 and 14 in the lateral direction. A plurality of extended portions 17 are formed at some positions of the linear portion 16, from which they are extended in the lateral direction. An external terminal (i.e. a ground terminal) 18 is formed in connection with one of the extended portions 17. Inner leads 19 are interconnected to and formed integrally with the ground terminal 18.

Three pairs of inner leads 21 and external terminals 22 (which are mutually connected together) are formed between the extended portions 17 of the shield plate 12 and are interconnected to the internal frame 11. Specifically, one pair of the inner lead 21 and the external terminal 22 is formed in the right side of the shield plate 12 in proximity to the ground terminal 18, while two pairs of the inner leads 21 and the external leads 22 are formed on the left side of the shield plate 12. In total, four pairs of inner leads and external terminals (i.e. the inner leads 19 and 21, and the external terminals 18 and 22) are formed in the lead frame 5 and are interconnected to the internal frame 11, wherein two pairs are formed in the right side of the shield plate 12, while the other two pairs are formed in the left side of the shield plate 12.

Similar to the projections 15, the external terminals 18 and 22 are increased in thickness and project in the backside. The projections 15 and the external terminals 18 and 22 are formed by performing half-etching on the backside of the lead frame 5. FIG. 8 shows the backside of the lead frame 5, wherein hatched regions are selectively subjected to half-etching.

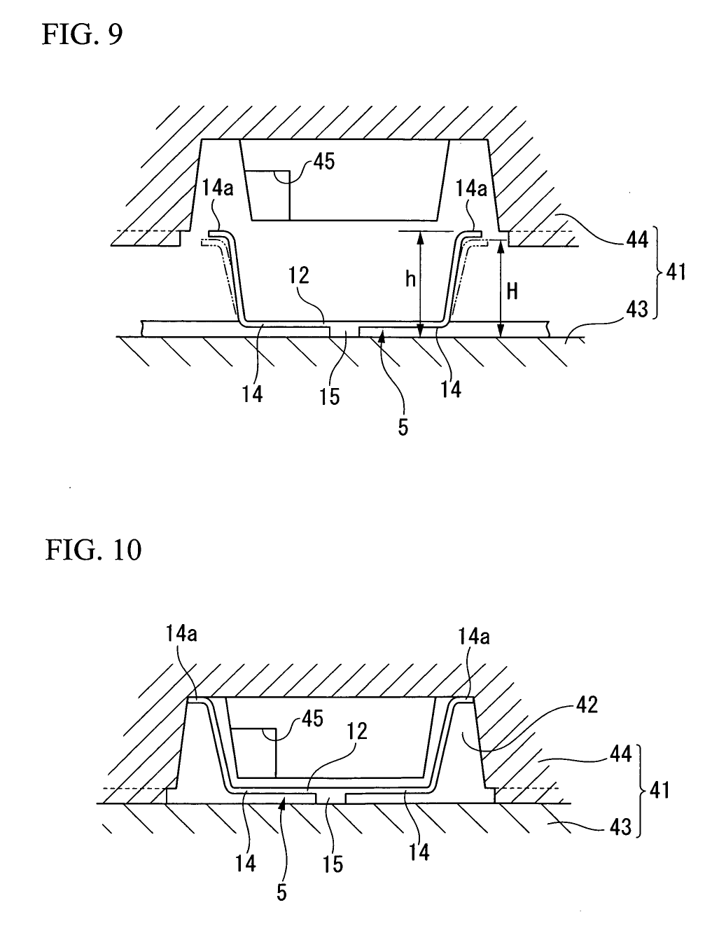

In FIG. 7, dashed lines indicate fold lines with respect to the arms 13 and 14 and the inner leads 19 and 21. Each of the arms 13 and 14 is folded (or bent) along two fold lines and is thus formed in a crank shape as shown in FIG. 1. The arms 13 and 14 are bent upwardly from the shield plate 12; then, the distal ends 13a and 14a thereof are further bent horizontally and are thus disposed in parallel with the shield plate 12. The distal ends 13a and 14a of the arms 13 and 14 are bent externally of the lead frame 5. As shown in FIG. 9, a height h is set between the surfaces of the distal ends 13a and 14a and the surfaces of the projections 15 (or the surfaces of the external terminals 18 and 22 of the shield plate 12). The height h is slightly larger than a height H of the mold resin 6 (see FIG. 4).

Similar to the arms 13 and 14, each of the inner leads 19 and 21 are folded along two fold lines and is thus formed in a crank shape, wherein distal ends 19a and 21a of the inner leads 19 and 21 are disposed in parallel with the shield plate 12. The heights of the distal ends 19a and 21a of the inner leads 19 and 21 are each set to approximately half the height of the pre-mold package 4.

The mold resin 6 is integrally formed together with the lead frame 5 having the aforementioned structure. As shown in FIGS. 4 and 5, the mold resin 6 is formed in a box-like shape constituted of a bottom 31 and a side wall 32 (which is vertically disposed on the bottom 31).

The shield plate 12, the base ends of the arms 13 and 14, and the base ends of the inner leads 19 and 21 are embedded in the bottom 31, while the surfaces of the projections 15 and the external terminals 18 and 21 (included in the lead frame 5) are exposed on the backside of the bottom 31. The side wall 32 is vertically disposed on the periphery of the bottom 31, wherein the intermediate portions of the arms 13 and 14 are embedded in the side wall 32. The distal ends 13a and 14a of the arms 13 and 14 are exposed on an upper end 32a of the side wall 32. The distal ends 13a and 14a of the arms 13 and 14 (i.e. six arms in total) are exposed on the upper end 32a of the side wall 32 at respective sides thereof as shown in FIG. 2 in such a way that the T-shaped distal ends 13a of the two main arms 13 are exposed on two opposite sides (i.e. upper and lower sides in FIG. 2) while the distal ends 14a of the four sub-arms 14 are exposed on other two sides (i.e. right and left sides in FIG. 2) in proximity to their opposite ends.

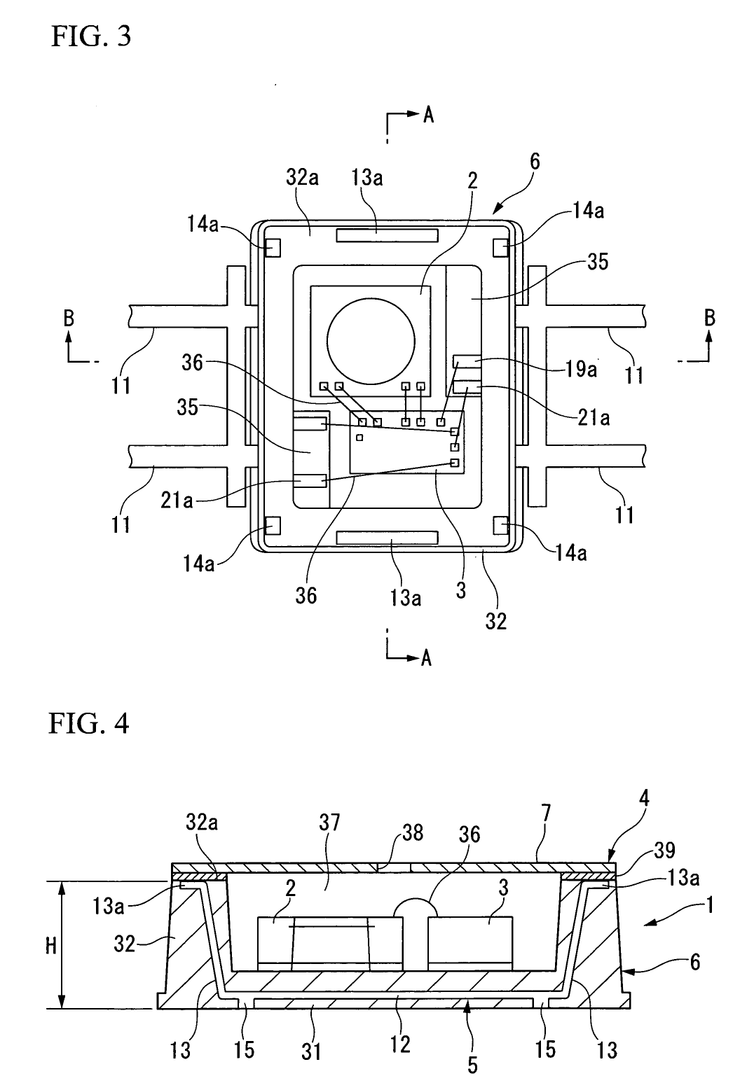

Two racks 35 are formed in a point symmetry with each other about the center of the bottom 31 in the mold resin 6, wherein each of them projects horizontally from the interior surface of the side wall 32 along the upper surface of the bottom 31. The height of the rack 35 is approximately half the height of the side wall 32. The distal ends 19a and 21a of the inner leads 19 and 21 are exposed on the surfaces of the racks 35. Two inner leads are arranged in each of the right and left sides of the shield plate 12 in the lead frame 5. Specifically, the two inner leads 21 are arranged on one side of the shield plate 12, while one inner lead 19 and one inner lead 21 are arranged on another side of the shield plate 12. Therefore, as shown in FIGS. 2 and 3, the distal ends 21a of the two inner leads 21 are exposed on the surface of the left-side rack 35, while the distal ends 19a and 21a of the inner leads 19 and 21 are exposed on the surface of the right-side rack 35.

The microphone chip 2 and the control chip 3 are affixed onto the surface of the bottom 31 via die-bond material beside the rack 35. The microphone chip 2 and the control chip 3 are connected together via bonding wires 36; and the control chip 3 is connected to the distal ends 19a and 21a of the inner leads 19 and 21 exposed on the surfaces of the racks 35 via bonding wires 36. The microphone chip 2 is constituted of a diaphragm electrode and a fixed electrode, which are positioned opposite each other. The microphone chip 2 detects variations of electrostatic capacitance due to vibrations of the diaphragm electrode (which vibrates due to pressure variations such as variations of sound pressure). The control chip 3 includes a power supply circuit for supplying an electric power to the microphone chip 2 and an amplifier for amplifying an output signal of the microphone chip 2.

The cover 7 is composed of a conductive metal material such as copper, stainless steel, and nickel silver. The cover 7 is formed in a rectangular shape in a plan view to substantially match the outline of the upper end 32a of the side wall 32. A sound hole 38 runs through the cover 7 at a prescribed position. When the cover 7 is attached to the mold resin 6, an internal space 37 communicates with the external space via the sound hole 38 of the cover 7. The cover 7 is attached to the upper end 32a of the side wall 32 via a conductive adhesive 39, thus covering the internal space 37 surrounded by the side wall 32. In this state, the cover 7 is electrically connected to the distal ends 13a and 14a of the arms 13 and 14, which are exposed on the upper end 32a of the side wall 32.

The internal frame 11 of the lead frame 5 is cut down at the periphery of the mold resin 6.

Next, a manufacturing method of the semiconductor device 1 will be described in detail.

First, a metal plate (not shown) is subjected to punching by way of press working, thus forming the lead frame 5. The lead frame 5 is subjected to half etching while the prescribed portions corresponding to the projections 15 and the external terminals 18 and 22 are masked, thus forming the projections 15 and the external terminals 18 and 22. Then, the lead frame 5 is subjected to bending, thus forming the aforementioned structure.

In the above, the height h between the surfaces of the distal ends 13a and 14a of the arms 13 and 14 and the surfaces of the projections 15 is slightly larger than the height H of the mold resin 6 (see FIG. 9).

Next, the lead frame 5 is arranged in a cavity 42 of an injection metal mold 41, which has a pair of metal molds 43 and 44 that are distanced from each other with a small gap therebetween. Herein, the internal frame 11 of the lead frame 5 is tightly held between the metal molds 43 and 44, wherein prescribed parts of the lead frame 5 such as the inner leads 19 and 21 and the shield plate 12, which are arranged inside of the internal frame 11, are arranged inside of the cavity 42. A resin material is injected into the cavity 42 of the injection metal mold 41 so that the lead frame 5 is completely embedded in the resin material, thus forming the mold resin 6.

FIG. 9 shows the opened state of the injection metal mold 41 in which the metal molds 43 and 44 are slightly distanced from each other, wherein the lead frame 5 is mounted on the lower metal mold 43. Herein, the surfaces of the projections 15 and the surfaces of the external terminals 18 and 22 are brought into contact with the interior surface of the lower metal mold 43 because the projections 15 and the external terminals 18 and 22 slightly project downwardly from the shield plate 12 in the backside of the lead frame 5. In this state, the upper metal mold 44 moves downward towards the lower metal mold 43 so that the distal ends 13a and 14a of the arms 13 and 14 first come in contact with the interior surface of the upper metal mold 44 because the height h between the surfaces of the distal ends 13a and 14a and the surfaces of the projections 15 are slightly larger than the height H of the mold resin 6. Thus, the lead frame 5 is clamped between the metal molds 43 and 44 while depressing the distal ends 13a and 14a of the arms 13 and 14.

Since the arms 13 and 14 are formed at the opposite ends of the shield plate 12, the arms 13 and 14 are elastically deformed about the projections 15 such that they are slightly broadened as shown in dashed lines in FIG. 9. FIG. 10 shows a completely clamped state in which the lead frame 5 is clamped between the metal molds 43 and 44, wherein due to restoration of the elastically deformed arms 13 and 14, the surfaces of the distal ends 13a and 14a come in contact with the interior surface of the upper metal mold 44 under pressure. In addition, due to restoration of the elastically deformed arms 13 and 14, the surfaces of the projections 15 and the surfaces of the external terminals 18 and 22 come in contact with the interior surface of the lower metal mold 43. The upper metal mold 4 has recesses 45 used for forming the racks 35; hence, the surfaces of the inner leads 19 and 22 are brought into contact with the top portions of the recesses 45 corresponding to the upper surfaces of the racks 35 inside of the injection metal mold 41.

In the clamped state of the injection metal mold 41, a melted resin is injected into the cavity 42 so as to form the mold resin 6, wherein due to the restoration of the elastically deformed arms 13 and 14, the projections 15 and the external terminals 18 and 22 come in contact with the interior surface of the lower metal mold 43 under pressure, while the distal ends 13a and 14a of the arms 13 and 14 come in contact with the interior surface of the upper metal mold 44 under pressure. This prevents the lead frame 5 from being unexpectedly moved inside of the cavity 42 defined between the metal molds 43 and 44 irrespective of the injection pressure of the melted resin. The melted resin is introduced into spaces defined between the distal ends 13a and 14a of the arms 13 and 14 and the interior surface of the lower metal mold 43, between the surfaces of the projections 15 and the interior surface of the upper metal mold 44, and between the surfaces of the external terminals 18 and 22 and the interior surface of the upper metal mold 44.

Thus, a relatively large portion of the lead frame 5 is embedded inside of the mold resin 6. In the mold resin 6, the distal ends 13a and 14a of the arms 13 and 14 are exposed on the upper end 32a of the side wall 32, while the external terminals 19 and 22 are exposed on the backside of the bottom 31. In addition, the inner leads 19 and 22 are partially exposed on the upper surfaces of the racks 35 that are formed inside of the side wall 32.

Then, the microphone chip 2 and the control chip 3 are affixed onto the surface of the bottom 31 of the mold resin 6 by way of die bonding and are connected to the inner leads 19 and 21 (exposed on the surfaces of the racks 35) by way of wire bonding. Thereafter, the cover 7 (which is independently prepared in advance) is bonded onto the upper end 32a of the side wall 32 (on which the distal ends 13a and 14a of the arms 13 and 14 are exposed) via the conductive adhesive 39.

In the aforementioned state, the pre-mold package 4 is connected to the internal frame 11 of the lead frame 5. Lastly, the internal frame 11 is subjected to cutting and is thus isolated from the periphery of the mold resin 6, thus completing the projection of the semiconductor device 1.

FIG. 6 shows the backside of the pre-mold package 4 of the semiconductor device 1, in which in total, four external terminals 18 and 22 are exposed on the backside. The pre-mold package 4 is mounted on a substrate (or a circuit board, not shown) by soldering the external terminals 18 and 22. In the packaging state, the shield plate 12 embedded in the bottom 31 of the mold resin 6 is positioned below the microphone chip 2 and the control chip 3; the distal ends 13a and 14a of the arms 13 and 14 connected to the shield plate 12 are exposed on the upper end 32a of the side wall 32 and are electrically connected to the cover 7 via the conductive adhesive 39; and the cover 7 is arranged over the microphone chip 2 and the control chip 3. That is, the microphone chip 2 and the control chip 3 are completely surrounded by the shield plate 12 and the cover 7; hence, it is possible to shield the microphone chip 2 and the control chip 3 from an external magnetic field when the ground terminal 18 connected to the shield plate 12 is grounded.

In the aforementioned shield structure, the distal ends 13a and 14a of the arms 13 and 14 are positioned upwardly and are exposed from the mold resin 6, while the other portions of the arms 13 and 14 are embedded in the side wall 32 of the mold resin 6; hence, they are not short-circuited with internal wirings such as bonding wires. Compared with interconnection leads (used in the foregoing conventional technology) whose intermediate portions are bent and exposed, it is possible to remarkably reduce the lengths of the distal ends 13a and 14a of the arms 13 and 14. The present embodiment requires the side wall 32 of the mold resin 6 to embed only the upwardly bent portions of the arms 13 and 14; hence, it is possible to reduce the thickness of the side wall 32. This makes it possible to reduce the overall size of the pre-mold package 4 and to reduce the manufacturing cost thereof.

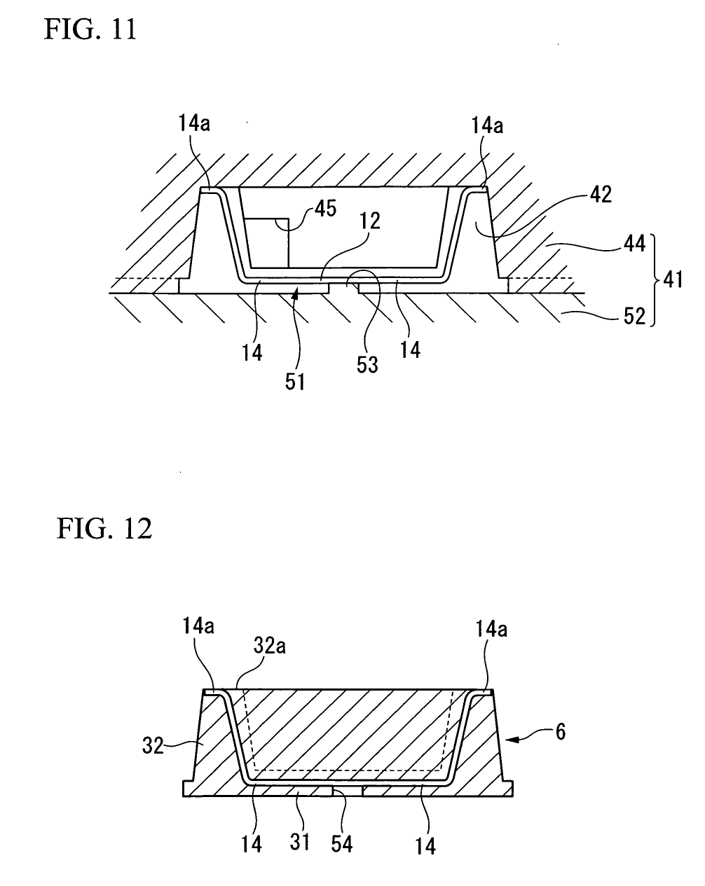

In the present embodiment, the projections 15, which project from the backsides of the branch portions of the arms 13 and 14 in the lead frame 5, are brought into contact with the interior surface of the lower metal mold 43 of the injection metal mold 41 so as to serve as fulcrums of elastic deformation of the arms 13 and 14 during clamping; but this is not a restriction. That is, it is possible to prepare a lead frame 51 having a flat backside, which is substantially identical to the lead frame 5 without the projections 15. In addition, the injection metal mold 41 is constituted of the upper metal mold 44 and a lower metal mold 52 having projections 53 as shown in FIGS. 11 and 12, wherein the backsides of the branch portions of the arms 14 are brought into contact with the projections 53 of the lower metal mold 52. In this case, as shown in FIG. 12, the mold resin 6 embedding the lead frame 51 has recesses 54 that are positioned to match the projections 53 of the lower metal mold 52, wherein the exposed portions of the lead frame 51 are positioned deeply inside of the recesses 54 of the mold resin 6. This may remarkably reduce the chance of causing short-circuiting due to soldering.

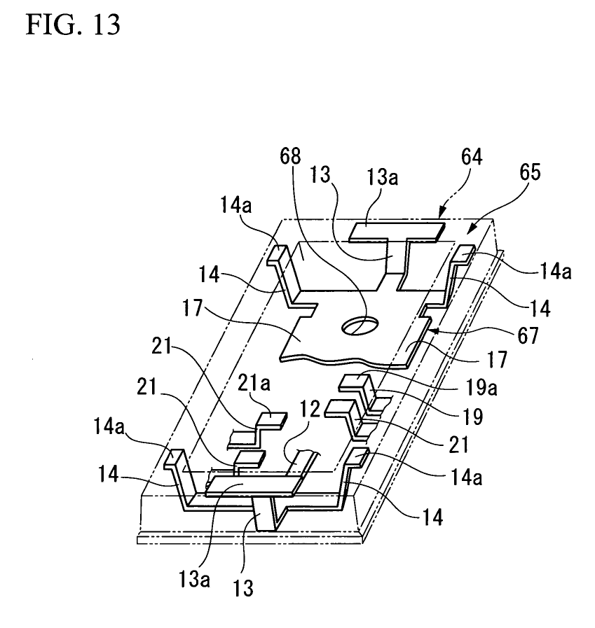

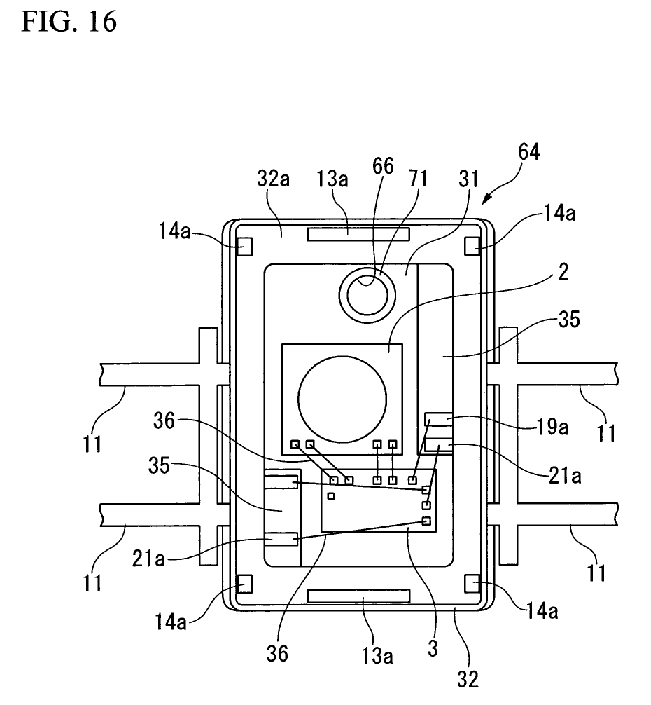

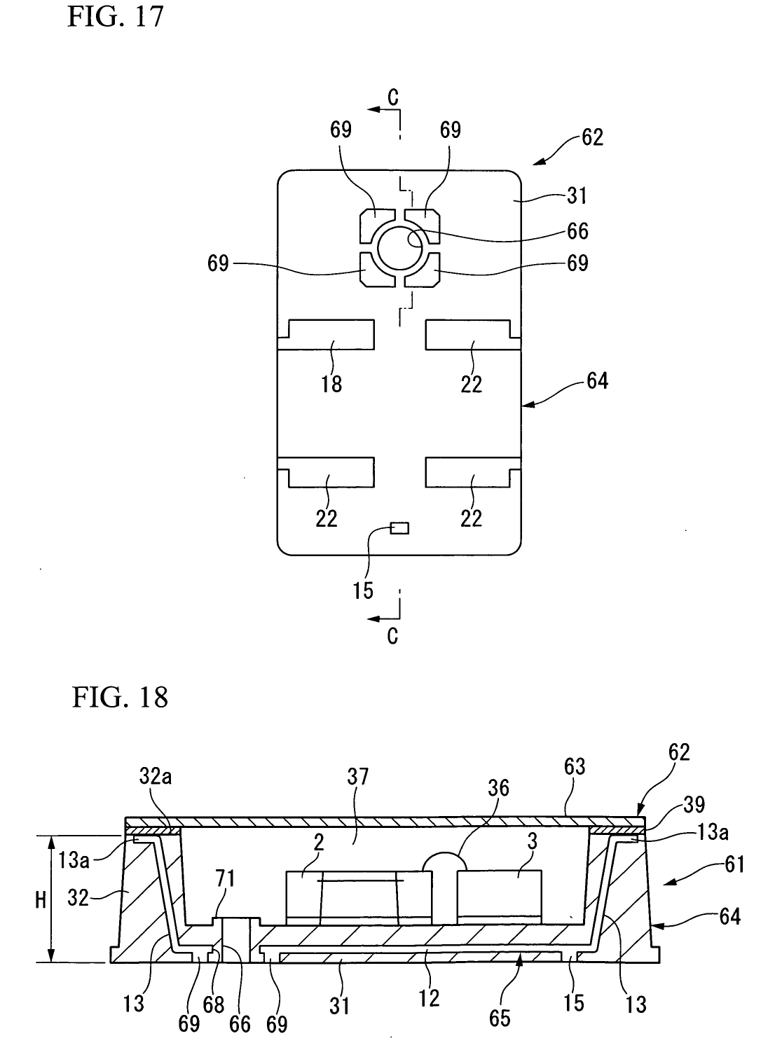

The first embodiment can be modified in a variety of ways; hence, a modified example of the first embodiment will be described in detail with reference to FIGS. 13 to 20, wherein parts identical to those shown in FIGS. 1 to 10 are designated by the same reference numerals; hence, detailed descriptions thereof will be omitted as necessary.

Similar to the semiconductor device 1 encapsulated in the pre-mold package 4, a semiconductor device 61 encapsulated in a pre-mold package 62 serves as a microphone. Compared with the cover 7 of the pre-mold package 4 having the sound hole 38, a cover 63 is formed as a flat plate having no hole as shown in FIG. 18 and is attached to the pre-mold package 62. Instead, a sound hole 66 is formed to run through a lead frame 65, which is embedded in a mold resin 64.

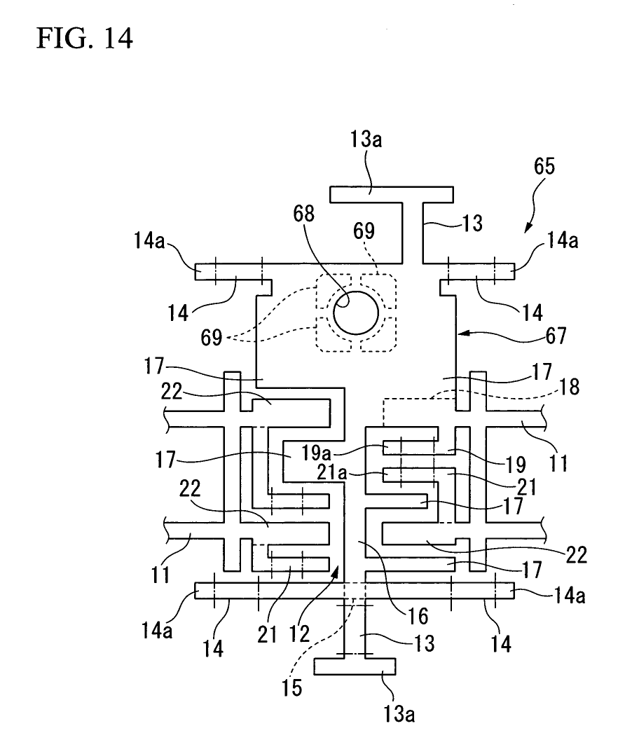

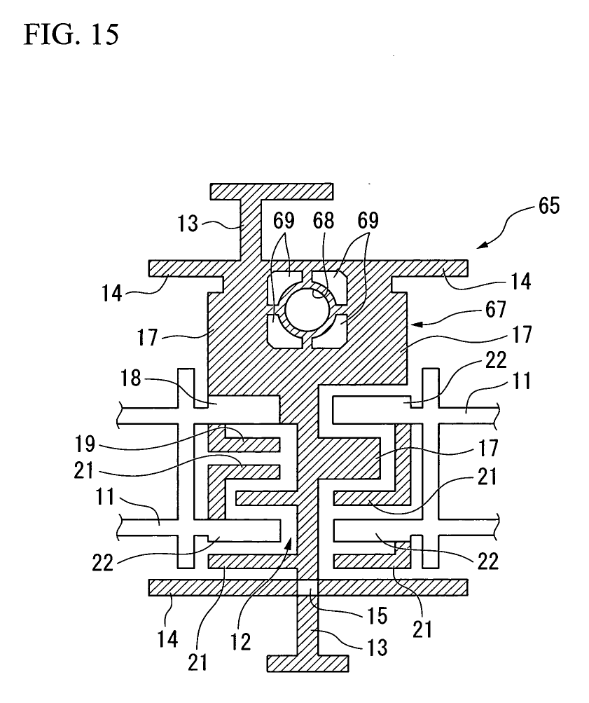

Similar to the lead frame 5 shown in FIGS. 1 and 7, the lead frame 65 shown in FIGS. 13 and 14 has a plurality of extended portions 17 in connection with the shield plate 12, in which one extended portion 17 positioned in proximity to one main arm 13 has a relatively large area so as to form a planar portion 67, in which a through-hole 68 is formed at approximately the center of the planar portion 67 in its width direction. External terminals 18 and 22 are formed in the backside of the lead frame 65 by way of half-etching similar to the lead frame 5. In addition, a plurality of projections 69 is formed in the surrounding area of the through-hole 68 such that the projections 69 are slightly distanced from the through-hole 68. In FIG. 15, hatched regions are subjected to half-etching.

The mold resin 64 is formed integrally with the lead frame 65, wherein the through-hole 66 runs through the bottom 31 of the mold resin 64. The diameter of the sound hole 66 is smaller than the diameter of the through-hole 68 running through the lead frame 65 embedded in the bottom 31 of the mold resin 64, wherein the through-hole 66 is positioned concentrically with the through-hole 68. A resin is formed in a cylindrical shape inside of the through-hole 68. The cylindrical portion of the resin projects upwardly from the bottom 31 so as to form a cylindrical projection 71 (see FIG. 18), which is extended towards the internal space 37 to establish communication with the sound hole 66.

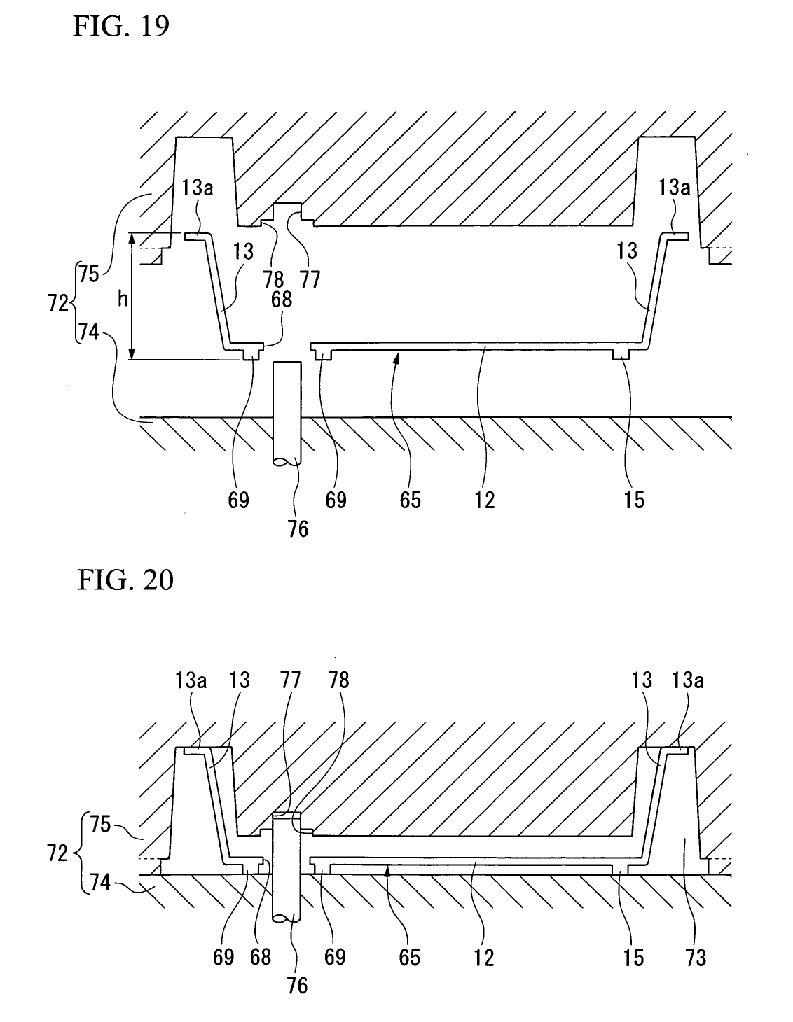

In manufacturing of the pre-mold package 62, a metal plate (not shown) is subjected to press working and half-etching so as to form the lead frame 65 shown in FIG. 13. As shown in FIG. 19, the lead frame 65 has projections 69 in addition to the projection 15 (which are included in the lead frame 5), wherein the height h between the surfaces 13a and 14a of the arms 13 and 14 and the surfaces of the projections 15 and 690 is slightly larger than the height H of the mold resin 64 (see FIG. 18).

The lead frame 65 is arranged in a cavity 73 of an injection metal mold 72, which is constituted of a pair of metal molds 74 and 75. A pin 76 is arranged between the metal molds 74 and 75, wherein the upper metal mold 75 has a hole 77 for inserting the upper end of the pin 76 and a counterbore 78 (whose diameter is slightly larger than the diameter of the hole 77 and which is formed concentrically with the hole 77). When the pin 76 is inserted into the hole 77, the counterbore 78 forms a cylindrical space around the pin 76.

When the metal molds 74 and 75 are clamped while the pin 76 is inserted into the through-hole 68 of the lead frame 65, the pin 76 runs through the cavity 73 of the injection metal mold 72 so as to positionally match the sound hole 66. In the clamped state, the projections 69 formed in the surrounding area of the through-hole 68 of the lead frame 65 are brought into contact with the interior surface of the lower metal mold 74, the projections 69 serve as fulcrums (similar to the projections 15 that positioned opposite to the projections 69 positioned in proximity to the sound hole 66), about which the distal ends 13a and 14a of the arms 13 and 14 are depressed and elastically deformed by the upper metal mold 75; hence, the distal ends 13a and 14a are firmly pressed to the interior surface of the upper metal mold 75.

In the clamped state, a melted resin is injected into the cavity 73 of the injection metal mold 72 so as to form the mold resin 64. The microphone chip 2 and the control chip 3 are affixed onto the bottom 31 of the mold resin 64 by way of die bonding. Subsequently, wire bonding is performed; then, the cover 63 is attached to the upper end 32a of the side wall 32. At this time, the cylindrical projection 71 formed to positionally match the sound hole 66 retains the adhesive used for die bonding, thus preventing it from unexpectedly flowing into the sound hole 66.

Since the sound hole 66 is formed in the mold resin 64, it is possible to reduce the overall height of the semiconductor device 61 mounted on a substrate (or a circuit board) incorporated in an electronic device such as a cellular phone.

The semiconductor devices 1 and 61 are not necessarily used for microphones; that is, they can be used for pressure sensors, acceleration sensors, magnetic sensors, flow sensors, and wind pressure sensors, for example. Microphones may each require a single sound hole communicating with the external space, whereas other sensors do not require sound holes, and flow sensors may each require two holes communicating with the external space.

The semiconductor devices 1 and 61 are encapsulated in the pre-mold packages 4 and 62, each of which has four external terminals serving as a power terminal, an output terminal, a gain terminal, and a ground terminal. The present embodiment simply requires multiple external terminals serving as a power terminal, an output terminal, and a ground terminal. Alternatively, it is possible to form two ground terminals. The number of external terminals depends upon the characteristics of semiconductor chips.

The arms are not necessarily formed at both the opposite ends of the shield plate 12. That is, the present embodiment simply requires that the distal ends of the arms be depressed and elastically deformed in the clamped state of the injection metal mold. The projections are not necessarily formed by way of half-etching; that is, it is possible to employ embossing and coining.

### 2. Second Embodiment

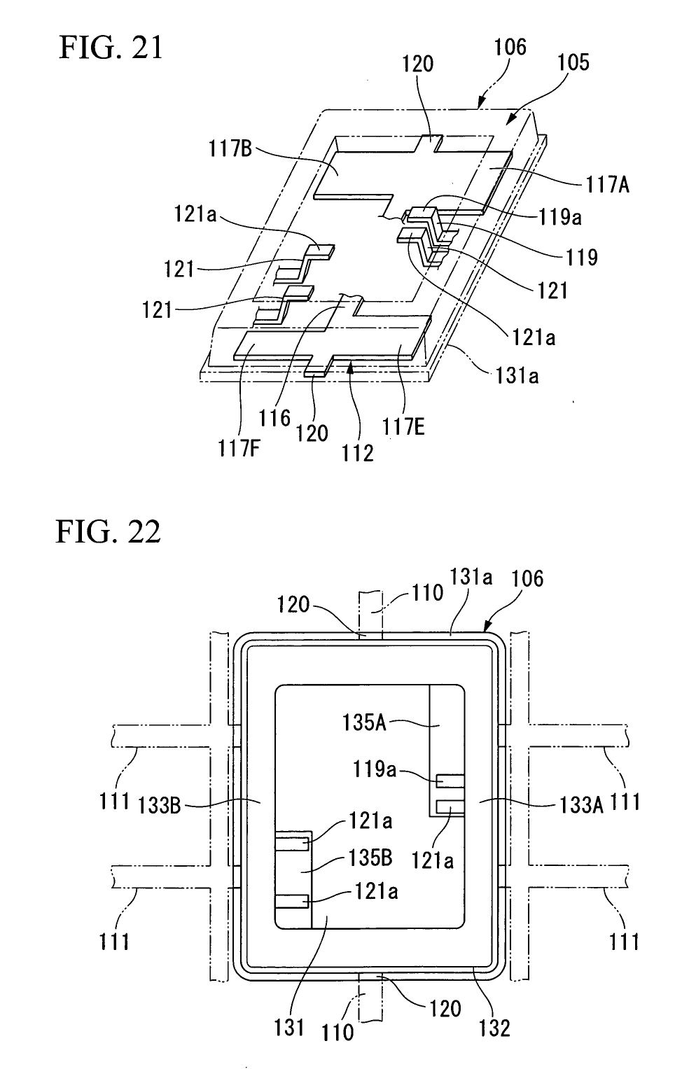

A semiconductor device 101 according to a second embodiment of the present invention will be described in detail with reference to FIGS. 21 to 31. The semiconductor device 101 serving as a microphone incorporates two semiconductor chips, i.e. a microphone chip 2 and a control chip 3.

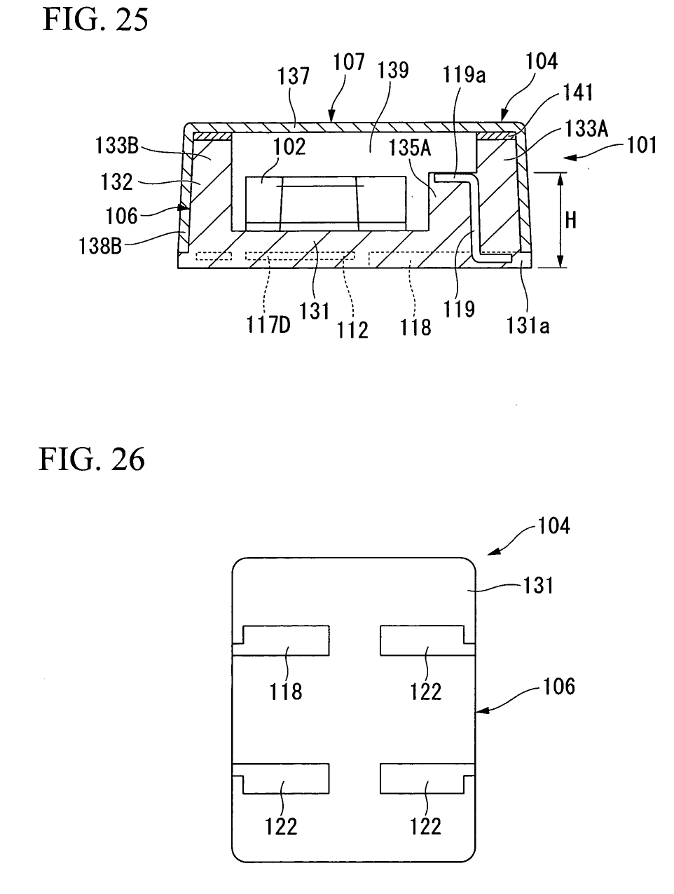

The semiconductor device 101 is encapsulated in a pre-mold package 104, which, as shown in FIGS. 24 and 25, is constituted of a lead frame 105, a mold resin 106 having a box-like shape (which is integrally formed with the lead frame 105), and a cover 107 for covering the mold resin 106.

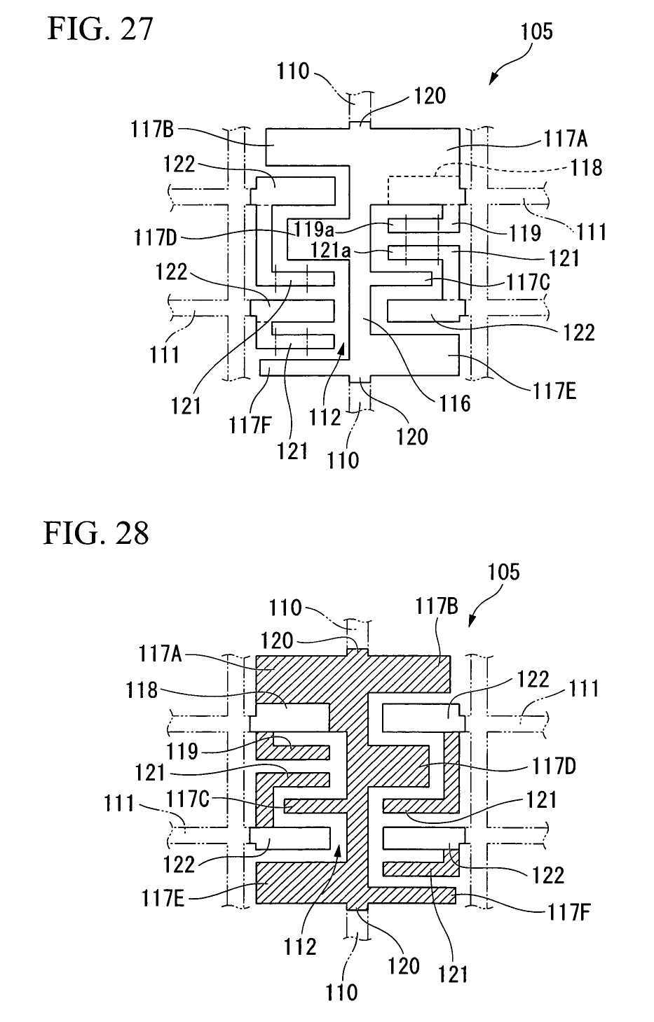

A metal plate is subjected to press working so as to form a single string of individual lead frames or multiple strings of individual lead frames, each of which corresponds to the lead frame 105 shown in FIG. 27. In FIG. 27, the vertical direction is referred to as the longitudinal direction, while the horizontal direction is referred to as the lateral direction. The lead frame 105 includes external frames 110 (which are formed at opposite ends in the longitudinal direction) and internal frames 111 (which are formed at opposite sides in the lateral direction), by which it is connected with another lead frame positioned adjacent thereto.

A shield plate 112 (which is elongated in the longitudinal direction) is formed in the center area of the lead frame 105. The shield plate 112 includes a plurality of extended portions 17A to 17F, which are extended in the lateral direction from a linear portion 116 (which is elongated in the longitudinal direction approximately in the center of the lead frame 105), wherein an external terminal (i.e. a ground terminal) 118 is formed in the extended portion 117A and is connected to and integrally formed with an internal terminal 119. The opposite ends of the linear portion 116 are interconnected to the external frame 110, which are cut out in the after-processing so as to form projections 120 (which project externally of the lead frame 105).

In total, three pairs of an internal terminal 121 and an external terminal 122 (which are mutually connected together) are arranged between the extended portions 117A to 117F of the shield plate 112. Specifically, one pair of the internal terminal 121 and the external terminal 122 is formed on the right side of the shield plate 112 in proximity to the ground terminal 118, while two pairs are formed on the left side of the shield plate 112, wherein the internal terminals 121 and the external terminals 122 are connected to the internal frames 111. In total, four pairs of internal terminals and external terminals are arranged in connection with the shield plate 112 and are connected to the internal frames 111, wherein two pairs are arranged in the right side of the shield plate 112, and the other two pairs are arranged in the left side of the shield plate 112.

The external terminals 118 and 122 are each increased in thickness compared with other portions of the lead frame 105 so as to project from the backside of the lead frame 105. In the present embodiment, the backside of the lead frame 105 is subjected to half-etching so that the external terminals 118 and 122 are projected from the backside of the lead frame 105. FIG. 28 shows the backside of the lead frame 105 shown in FIG. 27, in which hatched regions are selectively subjected to half-etching.

The external terminals 118 and 122 formed in the left side and the right side of the shield plate 112 are positioned opposite to each other with prescribed distances therebetween. In the backside of the lead frame 105 shown in FIGS. 26 and 28, the ground terminal 118 is positioned opposite to the first external terminal 122, while the second external terminal 122 is positioned opposite to the third external terminal 122 in connection with the shield plate 112.

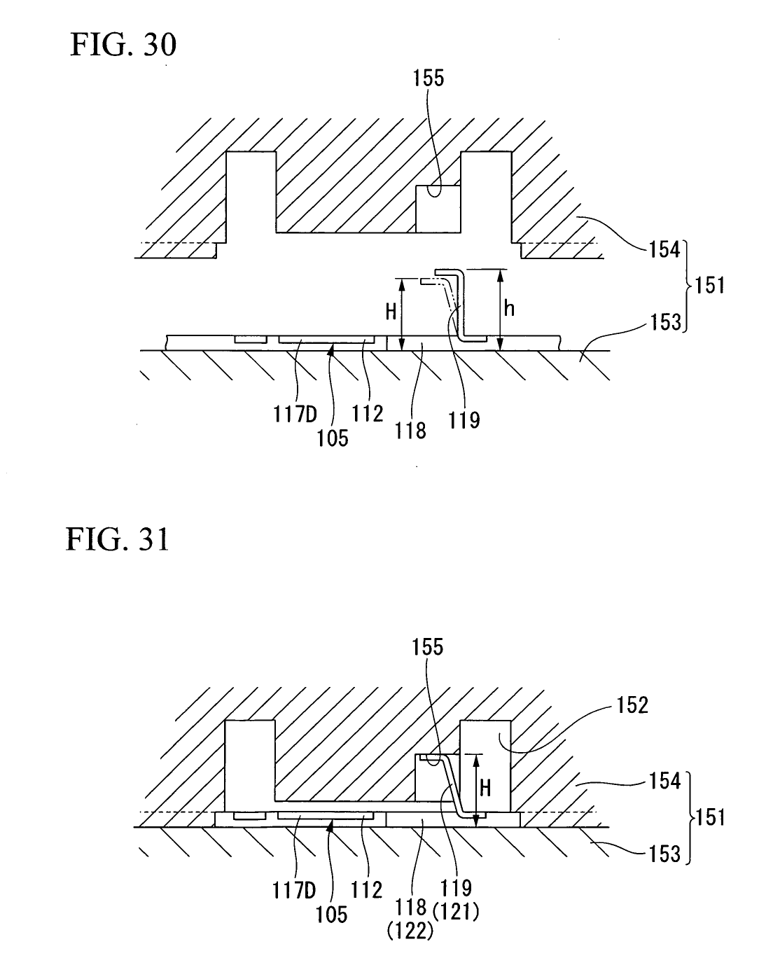

In FIG. 27, dashed lines indicate fold lines of the internal terminals 119 and 121. Each of the internal terminals 119 and 121 is bent along two fold lines; hence, the lead frame 105 is formed in a crank shape as shown in FIG. 21, wherein distal ends 119a and 121a of the internal terminals 119 and 121 are arranged in parallel with the shield plate 112. The height of the distal ends 119a and 121a of the internal terminals 119 and 121 is approximately half the overall height of the pre-mold package 104. As shown in FIGS. 25 and 30, a height h between the distal ends 119a and 121a of the internal terminals 119 and 121 and the surfaces of the external terminals 118 and 122 (which are formed in the backside of the lead frame 105) is slightly larger than the height H of racks 135A and 135B (which are formed in the mold resin 106).

The lead frame 105 is integrally formed with the mold resin 106. As shown in FIGS. 24 and 25, the mold resin 106 having a box-like shape is constituted of a rectangular bottom 131 (whose length is determined to allow the microphone chip 102 and the control chip 103 to adjoin together) and a side wall 132 vertically disposed on the periphery of the bottom 131.

The shield plate 112 and the base ends of the internal terminals 119 and 121 are embedded in the bottom 131 of the mold resin 106 such that the surfaces of the external terminals 118 and 122 of the lead frame 105 are exposed on the backside of the bottom 131. The side wall 132 is formed in a rectangular shape in a plan view, the outline of which is slightly smaller than the outline of the bottom 131, wherein the side wall 132 is vertically disposed on the periphery of the bottom 131 such that it is positioned slightly inward of the periphery of the bottom 131; hence, a peripheral portion 131a of the bottom 131 slightly projects externally of the side wall 132. The projections 120 of the shield plate 112 are exposed on the upper surface and circumferential surface of the peripheral portion 131a of the bottom 131.

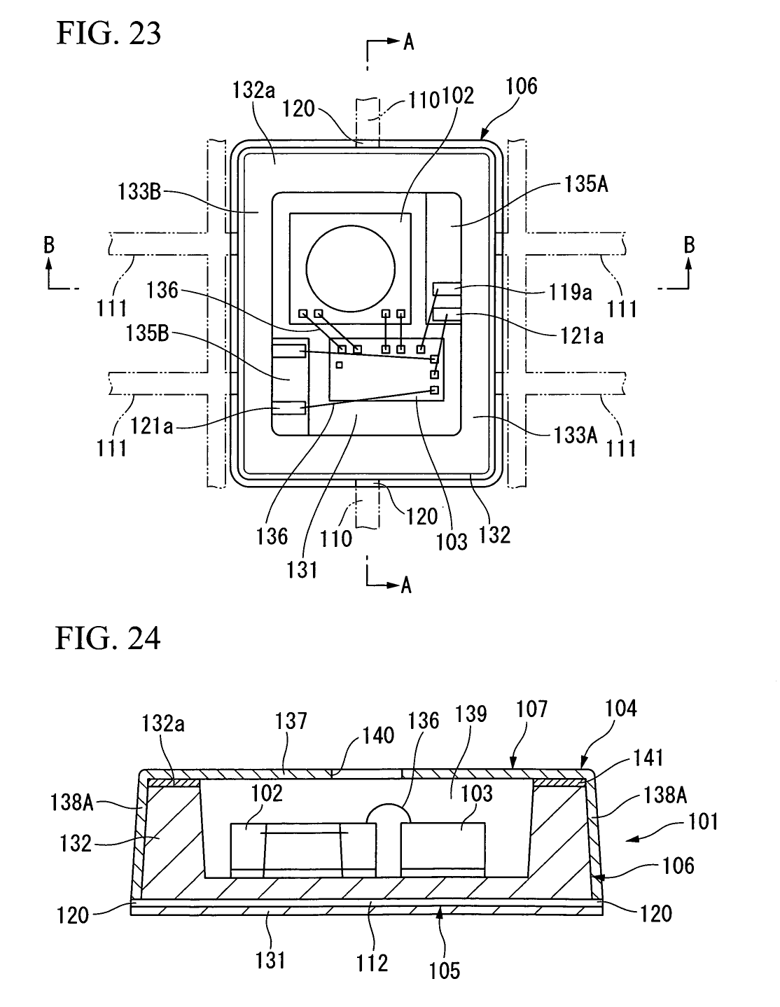

The side wall 132 of the mold resin 6 has two side portions 133A and 133B, which are positioned opposite to each other, wherein the racks 135A and 135B are integrally formed together with the interior surfaces of the side portions 133A and 133B. The lengths of the racks 135A and 135B in the longitudinal direction are each approximately half the length of the side portions 133A and 133B, wherein the racks 135A and 135B attached to the interior surfaces of the side portions 133A and 133B are mutually shifted from each other in positions in the longitudinal direction. That is, the racks 135A and 135B are positioned point-symmetrically about the center of the bottom 131 and are positioned alternately with each other in the longitudinal direction. In the present embodiment as shown in FIGS. 22 and 23, the rack 135A is slightly longer than the rack 135B in the longitudinal direction.

In addition, the heights of the racks 135A and 135B are each approximately half the height of the side wall 132. The distal ends 119a and 121a of the internal terminals 119 and 121 are exposed on the upper surfaces of the racks 135A and 135B. A pair of internal terminals (i.e 119 and 121) are formed in each of the left and right sides of the shield plate 112. Specifically, the internal terminals 119 and 121 are formed in the left side while the internal terminals 121 are formed in the right side of the shield plate 112. Thus, the distal ends 119a and 121a of the internal terminals 119 and 121 are exposed on the upper surface of the rack 135A (see the right side in FIGS. 2 and 3), while the distal ends 121a of the internal terminals 121 are exposed on the upper surface of the rack 135B (see the left side in FIGS. 2 and 3).

As shown in FIG. 3, the microphone chip 102 and the control chip 103 are affixed onto the surface of the bottom 131 by way of die bonding in such a way that the microphone chip 2 is arranged in the left-side space of the rack 135A while the control chip 103 is arranged in the right-side space of the rack 135B. The microphone chip 102 and the control chip 103 are electrically connected via bonding wires 136, while the control chip 103 and the racks 135A and 135B are electrically connected via bonding wires 136. The microphone chip 102 is constituted of a diaphragm electrode (that vibrates in response to variations of pressure as sound pressure) and a fixed electrode (both not shown), which are positioned opposite to each other, whereby it detects variations of electrostatic capacitance based on vibrations of the diaphragm electrode. The control chip 103 includes a power supply circuit (for supplying an electric power or a voltage to the microphone chip 102) and an amplifier (for amplifying output signals of the microphone chip 102).

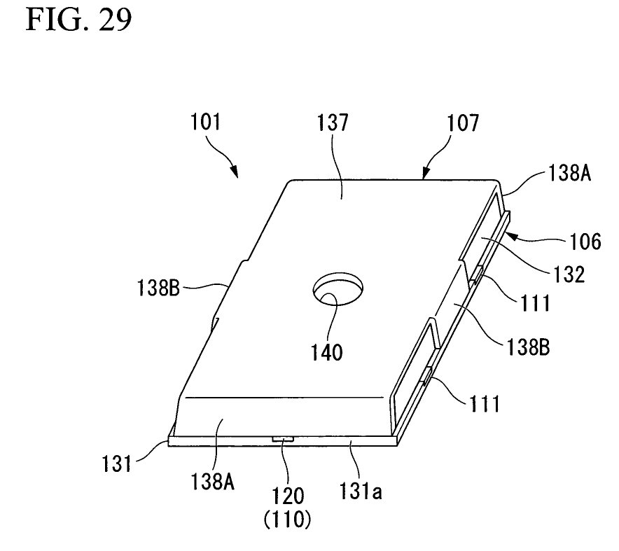

As shown in FIG. 29, the cover 107 (composed of a conductive metal material such as copper) is constituted of a top portion 137 (having a rectangular shape, which substantially matches the outline of the upper end 132a of the side wall 132) and a plurality of side portions 138A and 138B that are bent downward from the periphery of the top portion 137. All the side portions 138A and 138B of the cover 107 are positioned outside of the side wall 132 of the mold resin 106, wherein the side portions 138A are formed along two opposite sides of the top portion 137, while the side portions 138B are formed along other two opposite sides of the top portion 137. A sound hole 140 is formed at approximately the center of the top portion 137 of the cover 107 so as to communicate with an internal space 139 when the cover 107 is attached onto the mold resin 106.

The top portion 137 of the cover 107 is bonded onto the upper end 132a of the side wall 132 via a bonding material 141, whereby the internal space 139 surrounded by the side wall 132 is covered with the top portion 137 while the side portions 138A and 138B are fixed in position outside of the side wall 132, so that the internal space 139 communicates with the external space via the sound hole 140 of the top portion 137. The lower ends of the side portions 138A and 138B of the cover 107 are brought into contact with the peripheral portion 131a of the bottom 131, which slightly projects externally of the side wall 132. Since the side portions 138A and 138B lie along the four sides (or the centers of the four sides) of the top portion 137, the lower ends of the side portions 138A and 138B are brought into contact with the projections 120 (which project in the opposite ends of the shield plate 112) within the prescribed portions of the lead frame 105 that are exposed in the peripheral portion 131a of the bottom 131.

As shown in FIG. 29, the external terminal 110 and the internal terminal 111 initially attached to the lead frame 105 are cut out in the periphery of the mold resin 106.

Next, a manufacturing method of the semiconductor device 101 will be described with reference to FIGS. 30 and 31.

First, a metal plate (not shown) is subjected to punching or press working so as to form a thin metal plate, which is then subjected to half etching while masking prescribed portions corresponding to the external terminals 118 and 122; thereafter, it is subjected to bending, thus forming the lead frame 105 interconnected with the external frame 110 and the internal frame 111.

In the above, the height h of the distal ends 119a and 121a of the internal terminals 119 and 121 is slightly larger than the height H of the racks 135A and 135B.

Next, as shown in FIGS. 30 and 31, the lead frame 105 is arranged inside of a cavity 152 of an injection metal mold 151. The injection metal mold 151 has a pair of metal molds 153 and 154, which tightly hold and cramp the external frame 110 and the internal frame 111 therebetween so that the internal terminals 119 and 121 (formed inside of the internal frame 111) and the shield plate 112 are arranged inside of the cavity 152. Then, a melted resin is injected into the cavity 152 so as to form the mold resin 106 embedding the lead frame 105. Recesses 155 are formed in the upper metal mold 154 so as to form the racks 135A and 135B, wherein the distal ends 119a and 121a of the internal terminals 119 and 121 are brought into contact with the uppermost surfaces (or the bottoms) of the recesses 155 of the upper metal mold 154.

When the lead frame 105 is mounted on the lower metal mold 153 in the open state of the injection metal mold 151 as shown in FIG. 30, the surfaces of the external terminals 118 and 122 (which are project downwardly from the backside of the lead frame 105 compared with parts of the shield plate 112) come into contact with the interior surface of the lower metal mold 153. Then, the upper metal mold 154 is descended down towards the lower metal molds 153. Since the height h between the distal ends 119a and 121a of the internal terminals 119 and 121 and the external terminals 118 and 122 formed in the backside of the lead frame 105 is slightly larger than the height H of the racks 135A and 135B, the distal ends 119a and 121a of the internal terminals 119 and 121 first come into contact with the interior surface of the upper metal mold 154, so that clamping is performed while the upper metal mold 154 depresses the distal ends 119a and 121a.

When the upper metal mold 154 depresses the distal ends 119a and 121a, the internal terminals 119 and 121 are elastically deformed (see dashed lines in FIG. 30). In a clamped state shown in FIG. 31, due to the restoration of the elastically deformed internal terminals 119 and 121, the surfaces of the distal ends 119a and 121a are pressed to the internal surface of the upper metal mold 154. Due to the restoration of the elastically deformed internal terminals 119 and 121, the surfaces of the external terminals 118 and 122 (formed in the backside of the lead frame 105) are pressed to the internal surface of the lower metal mold 153.

In the clamped state of the injection metal mold 151, a melted resin is injected into the cavity 152 so as to form the mold resin 106, wherein due to the restoration of the elastically deformed internal terminals 119 and 121, the distal ends 119a and 121 of the internal terminals 119 and 121 are pressed to the internal surface of the upper metal mold 154 while the external terminals 118 and 122 are pressed to the internal surface of the lower metal mold 153, thus preventing the internal terminals 119 and 121 and the external terminals 118 and 122 from being unexpectedly moved due to the injection pressure of the melted resin. In addition, it is possible to prevent the melted resin from being unexpectedly introduced between the surfaces of the distal ends 119a and 121a of the internal terminals 119 and 121 and the internal surface of the upper metal mold 154 and between the surfaces of the external terminals 118 and 122 and the internal surface of the lower metal mold 153.

Therefore, a relatively large part of the lead frame 105 is embedded in the mold resin 106, while the distal ends 119a and 121a of the internal terminals 119 and 121 are exposed on the upper surfaces of the racks 135A and 135B in the mold resin 106, while the surfaces of the external terminals 118 and 122 are exposed on the backside of the bottom 131 of the mold resin 106.

The semiconductor chip 102 and the control chip 103 are fixed onto the bottom 131 of the mold resin 106 via die bonding; then, the control chip 103 is electrically connected to the distal ends 119a and 121a of the internal terminals 119 and 121 exposed on the upper surfaces of the racks 135A and 135B via wire bonding. Thereafter, the boding material 141 is applied to the upper ends 132a of the side wall 132; thus, the cover 107 (which is independently produced in advance) is bonded to the upper end 132a of the side wall 132 of the mold resin 106. In this state, the side portions 138A and 138B of the cover 107 are arranged outside of the side wall 132 of the mold resin 106, wherein, as shown in FIG. 29, the lower ends of the side portions 138A of the cover 107 comes in contact with the external frame 110 interconnected to the shield plate 120 whose prescribed portions are exposed in the peripheral portion 131a of the bottom 131 of the mold resin 106.

When the mold resin 106 is covered with the cover 107, the pre-mold package 104 is still connected to the external frame 110 and the internal frame 111 interconnected to the lead frame 105. Lastly, the external frame 110 and the internal frame 111 are cut out from the periphery of the mold resin 106, thus completing the production of the semiconductor device 101. When the external frame 110 and the internal frame 111 are cut out, as shown in FIG. 29, the cut ends of the internal frame 111 are exposed from the mold resin 106, while the projections 120 (which still remain after cutting out of the external frame 110) are brought into contact with the side portions 138A of the cover 107.

In the semiconductor device 101, as shown in FIG. 26, in total, four external terminals 118 and 122 are exposed on the backside of the pre-mold package 104. The semiconductor device 101 is mounted on a substrate (or a circuit board, not shown) such that the external terminals 118 and 122 are soldered onto the substrate. The shield plate 112, which is embedded in the bottom 131 of the mold resin 106 along the alignment direction of the microphone chip 102 and the control chip 103, is positioned below the microphone chip 102 and the control chip 103, so that the projections 120 positioned at the opposite ends of the shield plate 112 come in contact with the lower ends of the side portions 138A of the cover 107 (covering the upper portions of the microphone chip 102 and the control chip 103). That is, the microphone chip 102 and the control chip 103 are surrounded by the shield plate 112 and the cover 107, wherein the ground terminal 118 connected to the shield plate 112 is grounded so as to shield the microphone chip 102 and the control chip 103 from an external magnetic field.

In the semiconductor device 101, the internal terminals 119 and 121 are distributed to the racks 135A and 135B formed in the right and left sides of the mold resin 106. Compared with another structure in which all internal terminals are collectively arranged in one side of a mold resin, it is possible to reduce the concentration in wiring the internal terminals 119 and 121, which are thus appropriately distributed. This produces an adequate space in arranging the internal terminals 119 and 121. In addition, the microphone chip 102 and the control chip 103 can be positioned in the space between the racks 135A and 135B and between the side portions 133A and 133B of the side wall 132. This improves how efficiently space is used in the semiconductor device 101.

Since the internal terminals 119 and 121 are distributed to the racks 135A and 135B, as shown in FIG. 27, the right-side internal terminals 119 and 121 are interconnected to the right-side external terminals 118 and 122, while the left-side internal terminals 121 are interconnected to the left-side external terminals 122. This eliminates the necessity of interconnecting the internal terminals 119 and 121 and the external terminals 118 and 122 across the lead frame 105 in the lateral direction. That is, the shield plate 112 elongated in the longitudinal direction is arranged without being split along the entire length of the bottom 131; hence, it is possible to secure a relatively broad space in the semiconductor device 101. Compared with another structure in which internal terminals are arranged in the same plane, it is possible to reduce the distances between the internal terminals 119 and 121 and the shield plate 112 because the internal terminals 119 and 121 are upset (or overturned). This further increase the overall area of the shield plate 112, thus improving the shield effect.

Since the internal terminals 119 and 121 are distributed to the opposite side portions 133A and 133B of the side wall 132 of the mold resin 106, it is possible to simplify the structure for wiring the internal terminals 119 and 121 and the external terminals 118 and 122, which are interconnected together. In other words, it is possible to easily distribute the external terminals 118 and 122 to the side portions 133A and 133B of the side wall 132 of the mold resin 106.

Since the distal ends 119a and 121a of the internal terminals 119 and 121 (which are distributed to the side portions 133A and 133B of the side wall 132) are upset (or overturned), it is possible to reduce the distances between the external terminals 118 and 122 (which are distributed to the side portions 133A and 133B positioned opposite in the side wall 132). As a result, it is possible to reduce the size of the pre-mold package 104 and the mold resin 106 forming the semiconductor device 101.

The microphone chip 102 and the control chip 103 are electrically connected together via the bonding wires 136, and the control chip 103 is electrically connected to the distal ends 119a and 121a of the internal terminals 119 and 121 exposed on the upper surfaces of the racks 135A and 135B. In the present embodiment, both the upper surfaces of the racks 135A and 135B and the upper surfaces of the microphone chip 102 and the control chip 103 can be set to substantially the same height. This improves the bonding workability due to the distributed arrangement of the internal terminals 119 and 121.

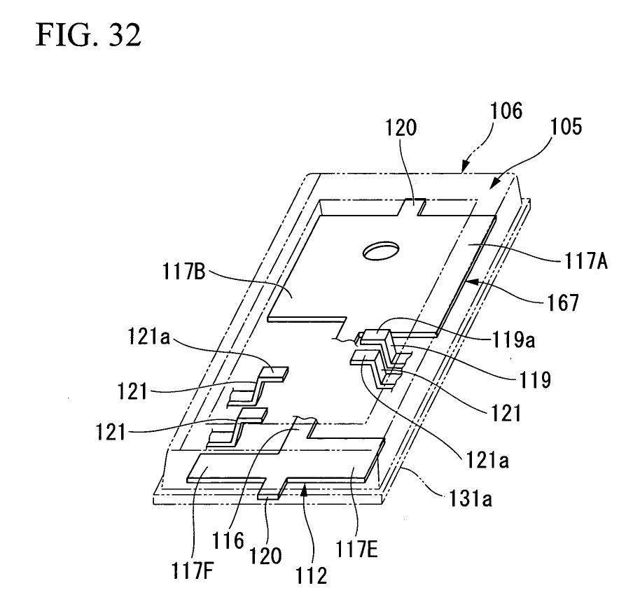

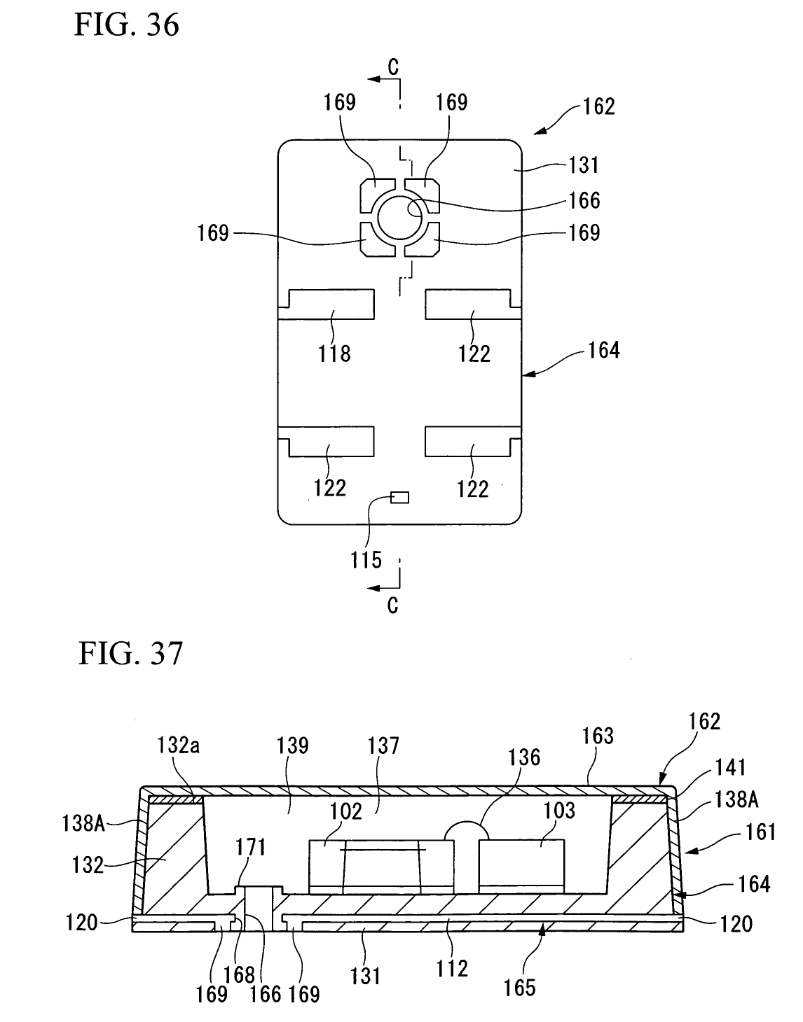

The second embodiment can be modified in a variety of ways. A semiconductor device 161 according to a modified example will be described with reference to FIGS. 32 to 39, in which parts identical to those of the semiconductor device 101 are designated by the same reference numerals; hence, the detailed descriptions thereof will be omitted as necessary.

Compared with the pre-mold package 104 of the semiconductor device 101 in which the sound hole 138 is formed in the cover 107, the pre-mold package 162 of the semiconductor device 161 (serving as a microphone) is designed such that, as shown in FIG. 37, a cover 163 is constituted of the top portion 137 (having no hole) and the side portions 138A and 138B (which are bent downwardly from four sides of the top portion 137), and a sound hole 166 is formed to run through a lead frame 165 embedded in a mold resin 164.

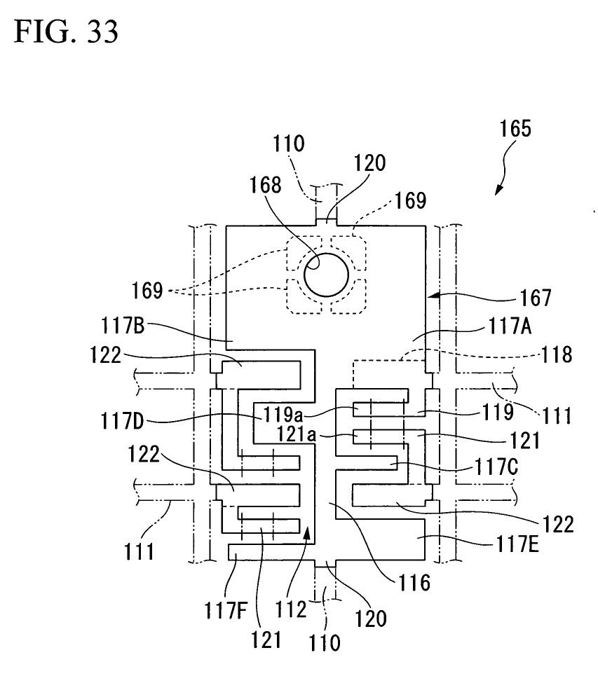

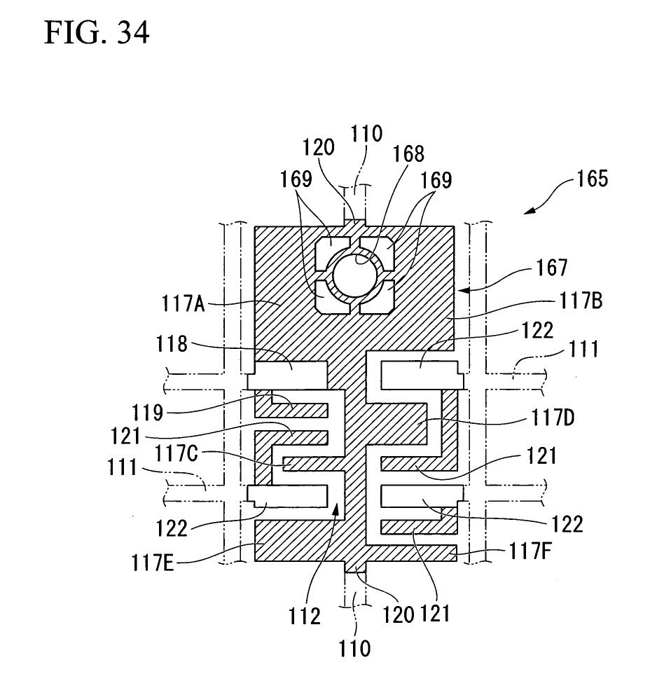

In the lead frame 165 as shown in FIGS. 32 and 33, the extended portions 117, which are formed on opposite ends of the shield plate 112 in the longitudinal direction so as to project from the linear portion 116, are interconnected together to form a planar portion 167, wherein a through-hole 168 is formed at substantially the center of the planar portion 167 in its width direction. Similar to the semiconductor device 101, the external terminals 118 and 122, which are formed in the backside of the lead frame 165, are formed by way of half-etching, wherein a plurality of projections 169 (see FIG. 33) are formed to surround the through-hole 168 in its periphery with small distances therebetween. FIG. 34 shows the backside of the lead frame 165, in which hatched portions are subjected to half-etching.

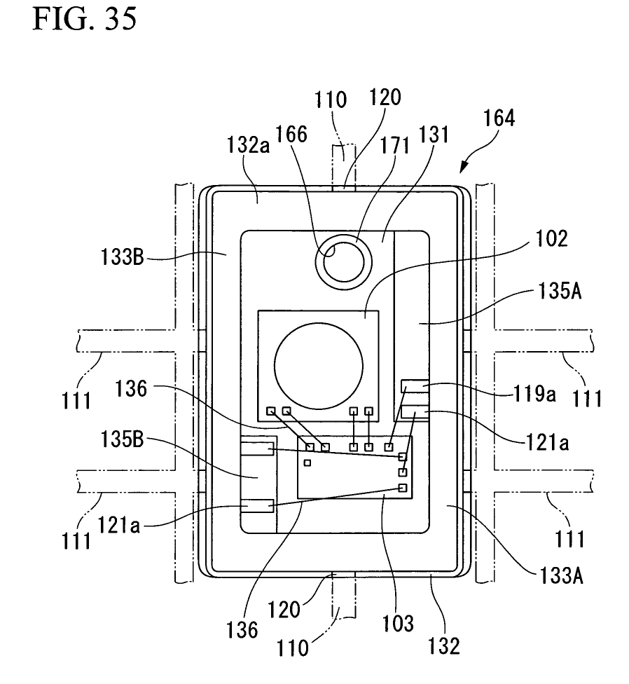

As shown in FIGS. 35 to 37, the mold resin 164 is integrally formed together with the lead frame 165, wherein the sound hole 166 is formed to run through the bottom 131 of the mold resin 164. The diameter of the sound hole 166 is smaller than the diameter of the through-hole 168 of the lead frame 165 embedded in the bottom 131 of the mold resin 164, wherein the sound hole 166 is formed concentrically with the through-hole 168. A cylindrical resin is formed inside of the through-hole 168 so as to project upwardly above the surface of the bottom 131, thus forming a cylindrical projection 171 which extends the opening of the sound hole 166 into the internal space 139.

In the manufacturing of the pre-mold package 162, a metal plate is subjected to press working and half-etching so as to form the lead frame 165 shown in FIG. 32. Similar to the semiconductor device 101 (see FIGS. 25 and 30), the height between the surfaces of the distal ends 119a and 121a of the internal terminals 119 and 121 and the surfaces of the external terminals 118 and 122 is slightly larger than the height H of the racks 135A and 135B in the lead frame 165.

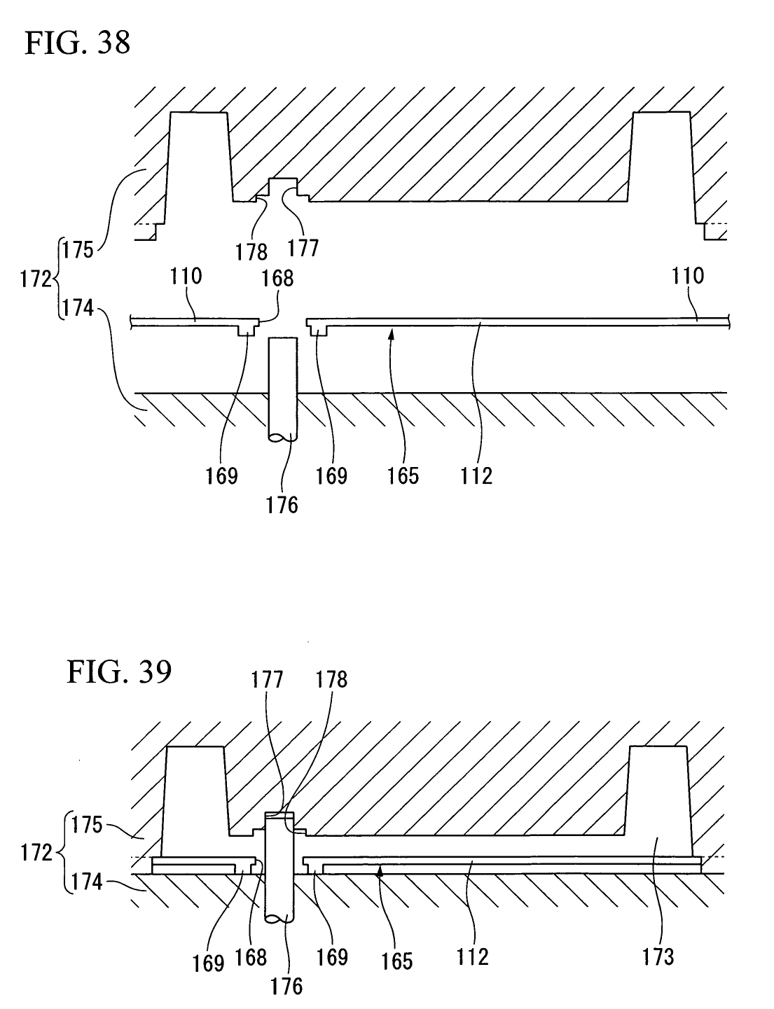

Next, as shown in FIGS. 38 and 39, the lead frame 165 is arranged inside of a cavity 173 of an injection metal mold 172 composed of metal molds 174 and 175. A pin 176 is formed to project upwardly from the lower metal mold 174, while a hole 177 (into which the distal ends of the pin 176 is inserted in a clamped state) and a counterbore 178 (whose diameter is slightly larger than the diameter of the hole 177) are concentrically formed in the upper metal mold 175. When the pin 176 is inserted into the hole 177, the counterbore 178 forms a cylindrical space around the pin 176. For the sake of convenience, FIGS. 38 and 39 do not show the recesses 155 (see FIGS. 30 and 31), which are formed in the upper metal mold 175 in order to form the racks 135A and 135B.

The lead frame 165 is mounted on the lower metal mold 174 in such a way that the pin 176 is inserted into the through-hole 168; then, the metal molds 174 and 175 are closed so that the distal end of the pin 176 is inserted into the cavity 173 so as to form the sound hole 166 in the mold resin 164. In the clamped state, the projections 169 surrounding the through-hole 168 of the lead frame 165 come in contact with the internal surface of the lower metal mold 174; hence, similar to the external terminals 118 and 122 of the semiconductor device 101 (see FIGS. 30 and 31), the interior surface of the upper metal mold 175 depresses the distal ends 119a and 121a of the internal terminals 119 and 121 (not shown in FIGS. 38 and 39), which are thus elastically deformed, whereby due to the restoration of the elastically deformed internal terminals 119 and 121, the surfaces of the projections 169 of the lead frame 165 are pressed to the interior surface of the lower metal mold 174.

In the clamped state of the injection metal mold 172, a melted resin is injected into the cavity 173 so as to form the mold resin 164. The microphone chip 102 and the control chip 103 are fixed onto the surface of the bottom 131 of the mold resin 164 via die bonding; then, wire bonding is performed with respect to the microphone chip 102, the control chip 103, and the distal ends 119a and 121a of the internal terminals 119 and 121. After completion of wire bonding, the cover 163 is fixed onto the upper end 132a of the side wall 132. At this time, the cylindrical projection 171 formed surrounding the sound hole 166 (running through the bottom 131 of the mold resin 164) blocks a die bonding material from flowing into the sound hole 166.

The semiconductor device 161 is characterized in that the sound hole 166 is formed in the mold resin 164; hence, when the semiconductor device 161 is mounted on a substrate (not shown) and is then incorporated into an electronic device such as a cellular phone, it is possible to reduce the height thereof.

The second embodiment is not necessarily limited to the semiconductor devices 101 and 161, which can be further modified in a variety of ways. The semiconductor devices 101 and 161 are each encapsulated in a surface mount package in which the external terminals 118 and 122 are exposed on the surfaces of the mold resins 106 and 164. Instead, it is possible to redesign them such that the external terminals are exposed on the side portions of the mold resins 106 and 164.

Each of the semiconductor devices 101 and 161 has four external terminals, namely, a power terminal, an output terminal, a gain terminal, and a ground terminal. The second embodiment simply requires at least two external terminals (serving as a power terminal, an output terminal, and a ground terminal). Of course, it is possible to increase the number of external terminals in conformity with the properties of semiconductor chips incorporated in each semiconductor device.

Each of the semiconductor devices 101 and 161 is adapted to a microphone package. Of course, the second embodiment can be applied to other types of semiconductor devices, for example, a semiconductor device in which at least one semiconductor chip is incorporated in a hollow pre-mold package. That is, the second embodiment can be adapted to pressure sensors, acceleration sensors, magnetic sensors, flow sensors, wind pressure sensors, and the like. The microphone package requires a through-hole such as a sound hole for establishing communication between the internal space and the external space. Some sensors do not require such a through-hole. Flow sensors may each require two through-holes, for example.

In this connection, the number of semiconductor chips incorporated in a mold resin is not limited to two.

Lastly, the present invention is not necessarily limited to the aforementioned embodiments and variations, which can be further modified in a variety of ways within the scope of the invention as defined by the appended claims.

What is claimed is:

1. A semiconductor device encapsulated in a pre-mold package, comprising:
a lead frame;
a mold resin having a box-like shape constituted of a side wall and a bottom for embedding the lead frame therein;
at least one semiconductor chip mounted on the bottom of the mold resin; and
a cover attached to an upper end of the side wall of the mold resin,
wherein the lead frame includes a shield plate embedded in the bottom of the mold resin, a plurality of arms extended from the shield plate, and a plurality of external terminals which are connected to either the shield plate or the semiconductor chip and are partially exposed on a backside of the bottom of the mold resin, and
wherein the cover is composed of a conductive material and is electrically connected to distal ends of the arms that are exposed on the upper end of the side wall of the mold resin.

2. The semiconductor device encapsulated in a pre-mold package according to claim 1, wherein the arms are embedded in the side wall of the mold resin.

3. A manufacturing method of a semiconductor device encapsulated in a pre-mold package, which includes
a lead frame,
a mold resin having a box-like shape constituted of a side wall and a bottom for embedding the lead frame therein,
at least one semiconductor chip mounted on the bottom of the mold resin, and
a cover attached to an upper end of the side wall of the mold resin,
wherein the lead frame includes a shield plate embedded in the bottom of the mold resin, a plurality of arms extended from the shield plate, and a plurality of external terminals which are connected to either the shield plate or the semiconductor chip and are partially exposed on a backside of the bottom of the mold resin, and
wherein the cover is composed of a conductive material and is electrically connected to distal ends of the arms that are exposed on the upper end of the side wall of the mold resin,
said manufacturing method comprising the steps of:
arranging the lead frame in a cavity of an injection metal mold;
clamping the lead frame in such a way that distal ends of the arms of the lead frame are depressed and elastically deformed; and
injecting a melted resin into the cavity so as to form the mold resin.

4. A mold resin used for a pre-mold package comprising:
a bottom for embedding the lead frame and for mounting a semiconductor chip thereon; and
a side wall vertically disposed in a periphery of the bottom,
wherein the lead frame includes a shield plate embedded in the bottom, a ground terminal that is connected to the shield plate and is exposed on a backside of the bottom, a plurality of external terminals that are electrically connected to a semiconductor chip mounted on the bottom and are partially exposed on a backside of the bottom, and a plurality of arms which are bend upwardly from the shield plate and whose distal ends are exposed on an upper end of the side wall.

5. A pre-mold package comprising:
a mold resin having a box-like shape constituted of a bottom for embedding a lead frame and for mounting a semiconductor chip thereon and side wall vertically disposed on a periphery of the bottom; and
a cover composed of a conductive material, which is fixed to an upper end of the side wall above the semiconductor chip,
wherein the lead frame includes a shield plate embedded in the bottom of the mold resin, a ground terminal that is connected to the shield plate and is exposed on a backside of the bottom, a plurality of external terminals that are electrically connected to the semiconductor chip and are exposed on the backside of the bottom, and a plurality of arms which are bent upwardly from the shield plate and whose distal ends are exposed on the upper end of the side wall and are thus electrically connected to the cover.

6. A pre-mold package according to claim 5, wherein the arms are embedded in the side wall.

7. A pre-mold package according to claim 5 further comprising a sound hole establishing communication between an internal space and an external space, wherein the semiconductor chip serves as a microphone chip.

8. A pre-mold package according to claim 7, wherein the sound hole is formed in the mold resin.

9. A semiconductor device comprising:
a plurality of semiconductor chips, which are electrically connected together;
a mold resin having a box-like shape, which is constituted of a bottom having a rectangular shape and a side wall vertically disposed on a periphery of the bottom, wherein the plurality of semiconductor chips is mounted on the bottom and is surrounded by the side wall;
a lead frame, which is constituted of a shield plate that is embedded in the bottom and is positioned below the plurality of semiconductor chips, a plurality of internal terminals electrically connected to at least one of the plurality of semiconductor chips, and a plurality of external terminals that are electrically connected to the plurality of internal terminals and that are exposed from the mold resin;
a plurality of racks, which are formed along an interior surface of the side wall so as to project above the bottom at respective positions that are oppositely shifted in a longitudinal direction and are adjacent to the plurality of semiconductor chips, wherein the plurality of internal terminals runs vertically through the plurality of racks so that distal ends of the internal terminals are exposed on upper surfaces of the racks; and
a cover for covering the mold resin to form an internal space therebetween, wherein the cover is composed of a conductive material and is electrically connected to the shield plate.

10. A semiconductor device according to claim 9, wherein the shield plate is elongated in an alignment direction of the semiconductor chips inside of the bottom of the mold resin.

11. A semiconductor device according to claim 9, wherein the plurality of semiconductor chips includes a microphone chip having a diaphragm and a control chip, wherein a sound hole establishing communication between an external space and the internal space formed between the mold resin and the cover is formed to run through the cover or the mold resin, and wherein the side wall of the mold resin has a pair of side portions, which are opposite to each other and along which the plurality of racks is integrally formed.

12. A manufacturing method for a semiconductor device, which is constituted of a plurality of semiconductor chips, a mold resin constituted of a bottom having a rectangular shape and a side wall vertically disposed on a periphery of the bottom, a lead frame constituted of a shield plate embedded in the bottom, a plurality of internal terminals electrically connected to at least one of the plurality of semiconductor chips, and a plurality of external terminals electrically connected to the plurality of internal terminals and exposed from the mold resin, a plurality of racks formed along an interior surface of the side wall at respective positions oppositely shifted in a longitudinal direction, and a cover for covering the mold resin, said manufacturing method comprising the steps of:
arranging the lead frame inside of a cavity of an injection metal mold constituted of a lower metal mold and an upper metal mold;
clamping the injection metal mold so as to tightly hold the lead frame between the lower metal mold and the upper metal mold, wherein distal ends of the internal terminals are pressed by an interior surface of the upper metal mold while the external terminals are placed in contact with an interior surface of the lower metal mold so that the internal terminals are elastically deformed; and
injecting a melted resin into the cavity so as to form the mold resin.

13. The manufacturing method for a semiconductor device according to claim 12, wherein the plurality of internal terminals runs vertically through the plurality of racks so that the distal ends of the internal terminals are exposed on upper surfaces of the racks, and wherein the cover is composed of a conductive material and is electrically connected to the shield plate.

14. The manufacturing method for a semiconductor device according to claim 12, wherein the plurality of semiconductor chips includes a microphone chip having a diaphragm and a control chip, wherein a sound hole establishing communication between an external space and an internal space formed between the mold resin and the cover is formed to run through the cover or the mold resin, and wherein the side wall of the mold resin has a pair of side portions, which are opposite to each other and along which the plurality of racks is integrally formed.

15. A mold resin comprising:
a bottom having a rectangular shape for substantially embedding a lead frame therein and used for mounting a plurality of semiconductor chips thereon;
a side wall vertically disposed on a periphery of the bottom,
wherein the lead frame is constituted of a shield plate embedded in the bottom, a plurality of internal terminals electrically connected to at least one of the plurality of semiconductor chips, and a plurality of external terminals that are electrically connected to the shield plate or the internal terminals and that are exposed on a backside of the bottom,
wherein a plurality of racks is formed along an interior surface of the side wall so as to project above the bottom at respective positions that are shifted alternately in a longitudinal direction and are adjacent to the plurality of semiconductor chips, and
wherein the plurality of internal terminals vertically runs through the plurality of racks so that distal ends of the internal terminals are exposed on upper surfaces of the racks.

16. A pre-mold package comprising:
a mold resin constituted of a bottom having a rectangular shape for substantially embedding a lead frame therein and used for mounting a plurality of semiconductor chips thereon and a side wall vertically disposed on a periphery of the bottom, wherein the lead frame is constituted of a shield plate embedded in the bottom, a plurality of internal terminals electrically connected to at lease one of the plurality of semiconductor chips, and a plurality of external terminals that are electrically connected to the shield plate or the internal terminals and that are exposed on a backside of the bottom; and
a cover that is fixed onto an upper end of the side wall so as to cover the mold resin, wherein the cover is composed of a conductive material and is electrically connected to the shield plate,
wherein a plurality of racks is formed along an interior surface of the side wall so as to project above the bottom at respective positions that are oppositely shifted in a longitudinal direction and are adjacent to the plurality of semiconductor chips, and
wherein the plurality of internal terminals vertically runs through the plurality of racks so that distal ends of the internal terminals are exposed on upper surfaces of the racks.

17. A microphone package comprising:
a mold resin constituted of a bottom having a rectangular shape for substantially embedding a lead frame therein and used for mounting a plurality of semiconductor chips thereon and a side wall vertically disposed on a periphery of the bottom, wherein the lead frame is constituted of a shield plate embedded in the bottom, a plurality of internal terminals electrically connected to at lease one of the plurality of semiconductor chips, and a plurality of external terminals that are electrically connected to the shield plate or the internal terminals and that are exposed on a backside of the bottom; and
a cover that is fixed onto an upper end of the side wall so as to cover the mold resin, wherein the cover is composed of a conductive material and is electrically connected to the shield plate,
wherein a plurality of racks is formed along an interior surface of the side wall so as to project above the bottom at respective positions that are oppositely shifted in a longitudinal direction and are adjacent to the plurality of semiconductor chips,
wherein the plurality of internal terminals vertically runs through the plurality of racks so that distal ends of the internal terminals are exposed on upper surfaces of the racks,
wherein a sound hole establishing communication between an external space and an internal space surrounded by the mold resin and the cover is formed to run through the mold resin or the cover, and
wherein the plurality of semiconductor chips includes a microphone chip that is arranged inside of the internal space.
